(19) United States
(12) Patent Application Publication
(10) Pub. No.: US 2022/0299877 A1
(43) Pub. Date: Sep. 22, 2022

(54) POSITIVE TONE DEVELOPMENT OF CVD EUV RESIST FILMS

(71) Applicant: Lam Research Corporation, Fremont, CA (US)

(72) Inventors: Timothy William Weidman, Sunnyvale, CA (US); Katie Lynn Nardi, San Jose, CA (US); Dries Dictus, Kessel-Lo (BE); Benjamin Kam, Heverlee, CA (US); Chenghao Wu, Berkeley, CA (US); Eric Calvin Hansen, San Jose, CA (US); Nizan Kenane, San Francisco, CA (US); Kevin Li Gu, Mountain View, CA (US)

(73) Assignee: Lam Research Corporation, Fremont, CA (US)

(21) Appl. No.: 17/753,110

(22) PCT Filed: Oct. 8, 2020
(86) PCT No.: PCT/US2020/054730

§ 371 Date: Feb. 18, 2022

Related U.S. Application Data
(60) Provisional application No. 62/912,330, filed on Oct. 8, 2019.

(51) Int. Cl. G03F 7/16; G03F 7/20; G03F 7/039

(52) U.S. Cl. CPC G03F 7/168; G03F 7/2004; G03F 7/039

(57) ABSTRACT

The present disclosure relates to post-application treatment of a radiation-sensitive film to provide a hardened resist film. In some instances, such films can be used to form a pattern by a positive tone wet development process.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### FIELD

This disclosure relates generally to the field of semiconductor processing. In particular aspects, the disclosure describes positive tone development of dry deposited (e.g., by chemical vapor deposition (CVD)), radiation-sensitive films.

### BACKGROUND

As semiconductor fabrication continues to advance, feature sizes continue to shrink, and new processing methods are needed. One area where advances are being made is in the context of patterning, for example using photoresist materials that are sensitive to lithographic radiation.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Various embodiments herein relate to methods, materials, apparatus, and systems for depositing a photoresist material on a substrate.

In a first aspect, the present disclosure encompasses a method including: providing a substrate to receive a pattern; applying a radiation-sensitive resist film on a surface of the substrate; conducting a post-application bake (PAB) or a post-application treatment of the radiation-sensitive resist film, thereby providing a hardened resist film; exposing the hardened resist film to a patterning radiation source, thereby providing an exposed resist film; and developing the exposed resist film to form a pattern by a positive tone wet development process.

In some embodiments, the film includes an Extreme Ultraviolet (EUV)-sensitive film. In other embodiments, the film includes iodine (I), indium (In), tin (Sn), bismuth (Bi), antimony (Sb), tellurium (Te), an oxide thereof, an alloy thereof, or a combination thereof. In particular embodiments, the film includes a first element having a high patterning radiation-absorption cross-section and a moiety that is cleavable under exposure to a patterning radiation. In some embodiments, the patterning radiation source is an EUV radiation source.

In some embodiments, said conducting including condensing the radiation-sensitive resist film by increasing a content of metal-oxygen-metal bonds and/or decreasing a content of metal-hydroxyl bonds.

In some embodiments, said applying includes a dry deposition process. In other embodiment, said applying includes deposition by sputtering, physical vapor deposition (PVD), chemical vapor deposition (CVD), atomic layer deposition (ALD), plasma-based deposition, thermal-induced decomposition, or plasma-induced decomposition of one or more precursors.

In some embodiments, said conducting includes: heating the radiation-sensitive resist film in an absence of an oxygen-containing gas at a temperature between about 190° C. to about 350° C. for about 10 seconds to 5 minutes. In other embodiments, said conducting further includes, after said heating: cooling the radiation-sensitive resist film in the presence of carbon dioxide (CO₂) at a low temperature. In yet other embodiments, said conducting further includes, after said heating: exposing the radiation-sensitive resist film to vacuum, an inert gas, or CO₂ at a temperature from about 0° C. to about 350° C. (e.g., from 20° C. to 350° C. or 23° C. to 350° C.) for a time period from about 10 seconds to 5 minutes.

In some embodiments, said conducting includes: exposing the radiation-sensitive resist film to vacuum, an inert gas, or CO₂ at a temperature between about 0° C. to about 350° C. (e.g., from 20° C. to 350° C. or 23° C. to 350° C.) for a time period between about 10 seconds to 5 minutes. In other embodiments, said conducting includes: heating or cooling the radiation-sensitive resist film in the presence of an inert gas or CO₂.

In some embodiments, the method further includes (e.g., after said exposing): treating the exposed resist film with an oxygen-containing agent. Non-limiting oxygen-containing agents include oxygen (O₂), ozone (O₃), or hydrogen peroxide (H₂O₂).

In some embodiments, the method further includes (e.g., after said exposing): storing the exposed resist film in an inert environment or under vacuum.

In some embodiments, said developing includes use of a developer selected from the group consisting of an alkaline developer, an acidic developer, and a deprotecting solvent. Non-limiting developers include a quaternary alkylammonium hydroxide, tetramethylammonium hydroxide (TMAH), choline, a halide, hydrogen chloride (HCl), hydrogen fluoride (HF), an organic acid, formic acid, acetic acid, oxalic acid, or citric acid. In other embodiments, the developer is a 0.5 wt. % to 10 wt. % solution and optionally includes an oxidizer, a non-ionic surfactant, a salt, and/or a chelating agent.

In some embodiments, said exposing includes: exposing the radiation-sensitive resist film to a patterned radiation exposure, thereby providing the exposed film resist having a radiation exposed area and a radiation unexposed area.

In other embodiments, said developing includes: removing the radiation exposed area to provide the pattern, wherein the radiation unexposed area includes a carbonate species.

In a second aspect, the present disclosure encompasses an apparatus for processing a substrate, the apparatus including: (a) one or more process chambers, each process chamber including a chuck or a pedestal; and (b) a controller having at least one processor and a memory, where the controller is configured to cause any method described herein.

In one embodiment, each process chamber includes a pedestal. In other embodiments, the apparatus includes one or more gas inlets into the process chambers and associated flow-control hardware; and one or more gas outlets for removing materials from the process chamber and associated flow-control hardware.

In particular embodiments, wherein at least one processor and the memory are communicatively connected with one another, and at least one processor is at least operatively connected with the flow-control hardware. In further embodiments, the memory stores computer-executable instructions for controlling the at least one processor to at least control the flow-control hardware and for causing any of method described herein.

In a third aspect, the apparatus includes a deposition module; a patterning module; a development module; and a controller including one or more memory devices, one or more processors, and system control software coded with instructions including machine-readable instructions.

In some embodiments, the deposition module includes a chamber for depositing a radiation-sensitive film (e.g., an EUV-sensitive film). In other embodiments, the patterning module includes a photolithography tool with a source of sub-300 nm wavelength radiation (e.g., in which the source can be a source of sub-30 nm wavelength radiation). In yet other embodiments, the development module includes a chamber for developing the resist film.

In particular embodiments, the controller instructions include machine-readable instructions for (e.g., in the deposition module) causing deposition of a precursor on a top surface of a substrate to form a film (e.g., a radiation-sensitive film). In other embodiments, the controller instructions include machine-readable instructions for (e.g., in the patterning module) causing patterning of the film with sub-300 nm resolution (e.g., or with sub-30 nm resolution) directly by patterned radiation exposure, thereby forming an exposed film having radiation exposed areas and radiation unexposed areas. In yet other embodiments, the exposed film has EUV exposed areas and EUV unexposed areas. In particular embodiments, the controller instructions include machine-readable instructions for (e.g., in the development module) causing development of the exposed film to remove the radiation exposed areas or the radiation unexposed areas to provide a pattern within the resist film. In other particular embodiments, the machine-readable instructions include instructions for causing removal of the EUV exposed areas or the EUV unexposed areas.

In some embodiments, the machine-readable instructions for causing deposition further include: instructions for causing deposition of an element having a high patterning radiation-absorption cross-section. In particular embodiments, the element has a high EUV absorption cross-section.

In some embodiments, the apparatus can further include: a cleaning module (e.g., including a chamber for cleaning the substrate or the film). In particular embodiments, the controller instructions include machine-readable instructions for (e.g., in the cleaning module) causing cleaning of a backside surface or a bevel of the semiconductor substrate after said deposition and/or causing removal of an edge bead of the film after said deposition.

In some embodiments, the apparatus can further include: a post-application treatment module. In particular embodiments, the controller instructions include machine-readable instructions for (e.g., in the bake module) causing conducting a post-application bake (PAB) or a post-application treatment of the radiation-sensitive resist film, thereby providing a hardened resist film, after said deposition.

In some embodiments, the apparatus can further include: a bake module. In particular embodiments, the controller instructions include machine-readable instructions for (e.g., in the bake module) causing baking of the film after said deposition and/or causing baking of the exposed film after said patterning.

In some embodiments, the apparatus can further include: an etch module. In particular embodiments, the controller instructions include machine-readable instructions for (e.g., in the etch module) causing etching or removing of the exposed film (e.g., removing of an exposed area or an unexposed area of the film) and/or the substrate after said patterning.

In any embodiment herein, the film includes an EUV-sensitive film, a DUV-sensitive film, a UV-sensitive film, a photoresist film, a photopatternable film, or a photoresponsive adhesive film.

In any embodiment herein, the film includes a metal or an atom having a high patterning radiation-absorption cross-section. In particular embodiments, the metal or the atom includes a high EUV absorption cross-section. In other embodiments, the metal-containing layer includes tin (Sn), bismuth (Bi), tellurium (Te), cesium (Cs), antimony (Sb), indium (In), molybdenum (Mo), hafnium (Hf), iodine (I), zirconium (Zr), iron (Fe), cobalt (Co), nickel (Ni), copper (Cu), zinc (Zn), silver (Ag), platinum (Pt), or lead (Pb), as well as combinations thereof.

In any embodiment herein, the precursor includes a metal or an atom having a high patterning radiation-absorption cross-section. In particular embodiments, the metal or the atom includes a high EUV absorption cross-section (e.g., equal to or greater than 1×10⁷ cm²/mol). In other embodiments, the precursor includes Sn, Bi, Te, Cs, Sb, In, Mo, Hf, I, Zr, Fe, Co, Ni, Cu, Zn, Ag, Pt, or Pb, as well as combinations thereof. In yet other embodiments, the precursor is a high photoabsorbing precursor (e.g., having a high Beer's absorption coefficient α, including an a of more than about 6 μm⁻¹).

In any embodiment herein, said applying includes providing one or more precursors. Non-limiting precursors include a structure having formula (I), (II), (IIa), (III), (IV), (V), (VI), (VII), or (VIII).

In any embodiment herein, said applying includes providing one or more precursors (e.g., any described herein, such as those including a structure having formula (I) or (II)) in the presence of the counter-reactant. Non-limiting counter-reactants include an oxygen-containing counter-reactant, including O₂, O₃, water, a peroxide, hydrogen peroxide, oxygen plasma, water plasma, an alcohol, a dihydroxy alcohol, a polyhydroxy alcohol, a fluorinated dihydroxy alcohol, a fluorinated polyhydroxy alcohol, a fluorinated glycol, formic acid, and other sources of hydroxyl moieties, as well as combinations thereof. Yet other non-limiting counter-reactants include a chalcogenide precursor having the formula ZR₂, wherein: Z is sulfur, selenium, or tellurium; and each R is, independently, H, optionally substituted alkyl (e.g., methyl, ethyl, n-propyl, isopropyl, n-butyl, t-butyl, etc.), optionally substituted alkenyl, optionally substituted aryl, optionally substituted amino, optionally substituted alkoxy, or optionally substituted trialkylsilyl.

In any embodiment herein, a single precursor is employed to deposit a layer or a film. In other embodiments, two or more different precursors are employed to deposit the layer.

In any embodiment herein, depositing includes providing or depositing the metal precursor(s) in vapor form. In other embodiments, depositing includes providing one or more counter-reactant(s) in vapor form. In particular embodiments, depositing includes CVD, ALD, or plasma-enhanced forms thereof.

In any embodiment herein, depositing of a layer further includes providing a counter-reactant. Non-limiting counter-reactants include an oxygen-containing counter-reactant or a chalcogenide precursor, including O₂, O₃, water, a peroxide, hydrogen peroxide, oxygen plasma, water plasma, an alcohol, a dihydroxy alcohol, a polyhydroxy alcohol, a fluorinated dihydroxy alcohol, a fluorinated polyhydroxy alcohol, a fluorinated glycol, formic acid, other sources of hydroxyl moieties, and ZR₂ (e.g., wherein Z is S, Se, or Te; and each R is, independently, H, optionally substituted alkyl, optionally substituted alkenyl, optionally substituted aryl, optionally substituted amino, optionally substituted alkoxy, or optionally substituted trialkylsilyl), as well as combinations thereof.

In any embodiment herein, the hardened resist film includes a metal-oxygen-metal species, a metal carbonate species, or a metal oxycarbonate species.

In any embodiment herein, the substrate includes a hard mask and/or an underlayer.

In any embodiment herein, the radiation-sensitive resist film includes an organometallic oxide film. In other embodiments, the radiation-sensitive resist film includes an organometallic oxide hydroxide film.

In any embodiment herein, the radiation-sensitive resist film includes tin (Sn), indium (In), bismuth (Bi), antimony (Sb), tellurium (Te), an oxide thereof, an alloy thereof, or a combination thereof.

Other features and advantages of the disclosure will be apparent from the following description and the claims.

### BRIEF DESCRIPTION OF THE DRAWINGS

FIG. 1A-1D presents reaction schemes of (A) a non-limiting first precursor (1) with water (H₂O) to provide a non-limiting organotin oxide material; (B) a non-limiting film subjected to PAB in air; (C) another non-limiting film subjected to PAB under inert conditions; and (D) yet another non-limiting film subjected to PAB under carbon dioxide (CO₂).

FIG. 2 presents a schematic diagram of a non-limiting method for making and using a resist film.

FIG. 3A-3D presents schematic block diagrams of non-limiting methods for making and using a resist film.

FIG. 4A-4B presents scanning electron microscopy (SEM) images of dry deposited films that were developed using (A) negative tone development process or (B) a positive tone development process.

FIG. 5 presents a series of SEM images of dry deposited films that were developed using a positive tone development process.

FIG. 6A-6B presents (A) non-limiting reaction schemes of a tin-based precursor having isopropyl as the EUV labile group and (B) mass spectrometry analysis showing the desorption of water, propene, and propane as a function of temperature. Water, propene, and propane are desorption products when annealed under ultrahigh vacuum (UHV).

FIG. 7A-7C presents data related to (A) film shrinkage under nitrogen gas (N₂), as a function of post-application bake (PAB) temperature, (B) extent of film shrinkage (in percentage) for PAB (at 200° C., 250° C., or 300° C.) under N₂ for 1 minute or 2 minutes; and (C) infrared (IR) spectroscopy analysis of films not subjected to PAB or subjected to PAB (from 200° C. to 290° C.) under N₂ for 2 minutes.

FIG. 8A-8B presents data showing remaining film after wet development with tetramethylammonium hydroxide (TMAH) for samples processed with (A) PAB under N₂ for 1 minute for various temperatures and (B) PAB under N₂ for 2 minutes for various temperatures.

FIG. 9 presents another series of SEM images of dry deposited films that were developed using a positive tone development process.

FIG. 10 presents a schematic illustration of an embodiment of a process station 600 for dry development.

FIG. 11 presents a schematic illustration of an embodiment of a multi-station processing tool 700.

FIG. 12 presents a schematic illustration of an embodiment of an inductively coupled plasma apparatus 800.

FIG. 13 presents a schematic illustration of an embodiment of a semiconductor process cluster tool architecture 900.

FIG. 14 depicts a cross-sectional schematic view of an example of a dry deposition apparatus 1000.

### DETAILED DESCRIPTION

Reference is made herein in detail to specific embodiments of the disclosure. Examples of the specific embodiments are illustrated in the accompanying drawings. While the disclosure will be described in conjunction with these specific embodiments, it will be understood that it is not intended to limit the disclosure to such specific embodiments. On the contrary, it is intended to cover alternatives, modifications, and equivalents as may be included within the spirit and scope of the disclosure. In the following description, numerous specific details are set forth in order to provide a thorough understanding of the present disclosure. The present disclosure may be practiced without some or all of these specific details. In other instances, well known process operations have not been described in detail so as to not unnecessarily obscure the present disclosure.

Patterning of thin films in semiconductor processing is often an important step in the fabrication of semiconductors. Patterning involves lithography. In conventional photolithography, such as 193 nm photolithography, patterns are printed by emitting photons from a photon source onto a mask and printing the pattern onto a photosensitive photoresist, thereby causing a chemical reaction in the photoresist that, after development, removes certain portions of the photoresist to form the pattern.

Advanced technology nodes (as defined by the International Technology Roadmap for Semiconductors) include nodes 22 nm, 16 nm, and beyond. In the 16 nm node, for example, the width of a typical via or line in a Damascene structure is typically no greater than about 30 nm. Scaling of features on advanced semiconductor integrated circuits (ICs) and other devices is driving lithography to improve resolution.

Extreme ultraviolet (EUV) lithography can extend lithography technology by moving to smaller imaging source wavelengths than would be achievable with conventional photolithography methods. EUV light sources at approximately 10-20 nm, or 11-14 nm wavelength, for example 13.5 nm wavelength, can be used for leading-edge lithography tools, also referred to as scanners. The EUV radiation is strongly absorbed in a wide range of solid and fluid materials including quartz and water vapor, and so operates in a vacuum.

Traditional organic chemically amplified resists (CAR) have a few drawbacks when used in EUV lithography, particularly low absorption coefficient in EUV region and acid diffusion of photo-activated chemical species. To overcome the low absorption coefficient, a relatively thick CAR film is necessary, but at the risk of pattern collapse. Moreover, the broad clearing radius during the acid diffusion process leads to relatively high line roughness in patterned CAR films. Quenchers may be used to reduce the acid diffusion radius, but at the cost of decreased sensitivity. As such, the lithographic performance of current CARs is unable to reach the desired EUV lithographic performance.

Directly photopatternable EUV resists containing metals and/or metal oxides mixed within organic components show promise in that they can enhance the EUV photon absorption and generate secondary electrons and/or show increased etch selectivity to an underlying film stack and device layers. Spin-on organometallic resists, such as are available from Inpria Corp., Corvallis, Oreg., have a substantially higher absorption coefficient than CARs and can be significantly thinner while still providing good etch resistance. Dry deposition of metal-organic based photopatternable EUV resists has also been described, for example in our prior International Application PCT/US19/31618, published as International Pub. No. WO2019/217749, filed May 9, 2019, and titled METHODS FOR MAKING EUV PATTERNABLE HARD MASKS, the disclosure of which relating to the composition, dry deposition, and patterning of directly photopatternable metal-organic based metal oxide films to form EUV resist masks is incorporated by reference herein. Prior descriptions of these dry deposited metal-organic based resists have involved negative tone development of the EUV resist films.

This disclosure provides a process for the positive tone wet development of radiation-sensitive resist film. In some embodiments, the film is dry deposited. In some instances, dry deposition can include, e.g., chemical vapor deposition (CVD) to provide an organometallic oxide photopatternable EUV resist film. Previous approaches for developing these films using either wet (e.g., organic solvents) or dry etch techniques (e.g., HBr, HCl, BCl₃) produced negative tone patterns. Positive tone development of such films has now been achieved.

In particular, use of a post-application bake (PAB) or other post-application treatment provides a resist film that be employed in a positive development process. For instance, post-application treatment can further cross-link the unexposed resist film to provide a hardened resist film. This hardened film can include metal-oxygen-metal (M-O-M) bonds, which are more resistant to etching. If the resist film includes EUV labile groups attached to metal centers, then EUV exposed regions can include cleaved moieties, such as M-H and/or M-OH bonds, that can be more readily etched. In this way, etch selectivity can be tuned to provide a positive tone resist.

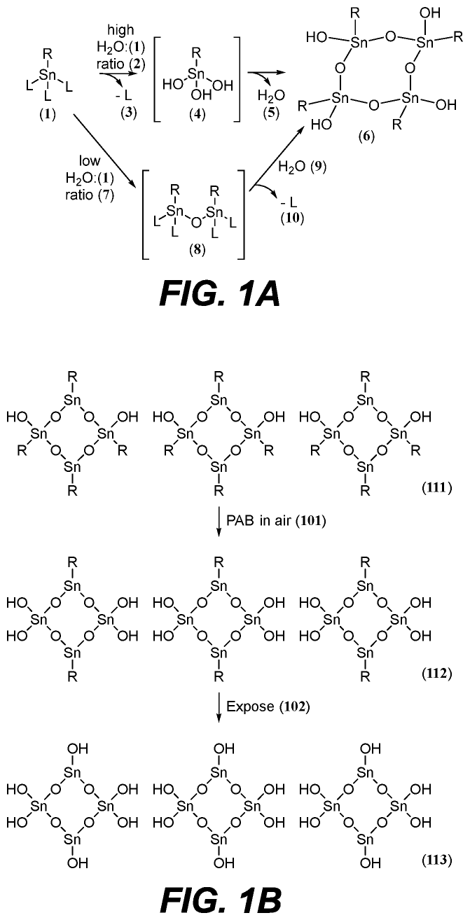

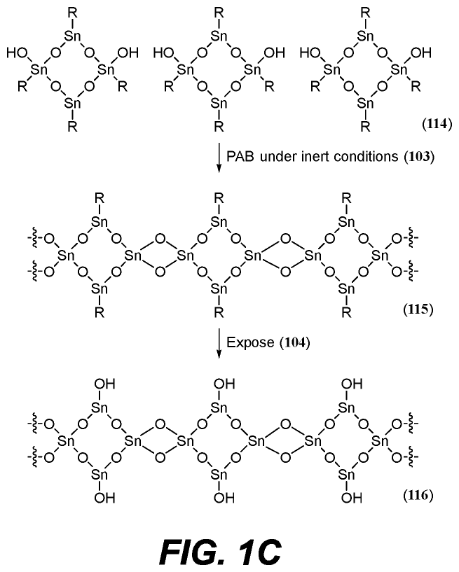

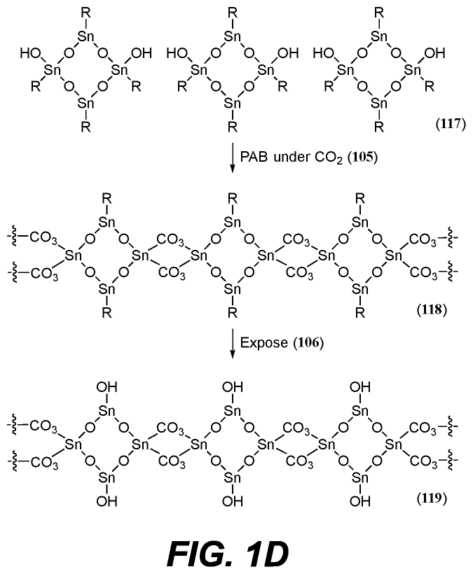

In one instance, FIG. 1A provides a non-limiting schematic of a gas phase hydrolysis, condensation, and polymerization mechanism for depositing a resist film. The non-limiting precursor (1) includes R (a radiation-sensitive moiety or a labile moiety cleaved by radiation) and L (a leaving group). R can be an alkyl group that is hydrolytically stable but participates in an EUV labile Sn—C bond. L can be an easily displaced leaving group in the presence of a counter-reactant, such as H₂O. Further examples of precursors are described herein.

The precursor can provide various intermediates. As seen in FIG. 1A and without limitation, a high ratio of H₂O to compound (1) (denoted as (2)) can provide intermediate (4), in which L groups (3) are readily displaced due to the excess presence of H₂O. This intermediate (4), in turn, can lose water (5) (e.g., such as with a PAB or other post-application treatment) to form an oligomeric species (6). Alternatively, a low ratio of H₂O to compound (1) (denoted as (7)) can provide intermediate (8), in which some but not all L groups (10) are displaced. This allows for the formation of dimeric intermediates, such as intermediate (8), which in turn can provide an oligomeric species (6) in the presence of water (9) or another oxygen-containing counter-reactant. An oligomeric species can have 6 to 8 member rings and likely result from gas phase (or wafer surface) condensation reactions of hydroxy tin precursors with bulky R substituents. For this process, surface condensation may occur long before polymerization to large, higher molecular weight products. The process in FIG. 1A can be used with any precursor and counter-reactant described herein to form an organometallic oxide hydroxide film.

A typical high temperature post-application bake (PAB) in the presence of oxygen gas (O₂) can be conducted after film deposition but before film exposure. As seen in FIG. 1B, a deposited film (111) can be treated with high temperature PAB (101) with O₂ (as present in ambient air or as provided as pure O₂), which can result in a film (112) having hydroxyl-rich products. After exposure (102), the exposed film (113) also includes hydroxyl-rich products (formed from cleaved, reactive M-H moieties, which readily covert to M-OH in the presence of oxygen or water). Due to a similar chemical composition between the material before and after exposure, the film may not yield a differential solubility contrast.

In some instances, low temperature PAB (e.g., less than about 250° C., less than about 190° C., or even less than about 170° C.) can be used to provide sufficiently dehydrated films. For low temperature PAB, exposure to higher temperatures can include use of shorter time periods, and exposure to lower temperatures can include use of longer time periods. In non-limiting embodiments, low temperature PAB includes a temperature from about 100° C. to about 200° C., including from 100° C. to 190° C., 140° C. to 190° C., or 140° C. to 200° C. Time periods can include for about 10 seconds to 5 minutes, including a period from about 30 seconds to 5 minutes.

Post-application treatment can also include the use of an oxygen-free environment (e.g., a vacuum or an inert gas) or use of CO₂ to influence the type of species within the film. Accordingly, the present disclosure also relates to the use of annealing and/or cooling conditions that provide hardened films having a higher molecular weight material. In some instances, the process removes some (but not all) radiation-sensitive moieties from a deposited film in order to form a film having a denser, higher molecular weight material. Initially, a deposited film can include a variety of species, including radiation-sensitive moieties (e.g., R in formula (I) or (II) herein), metal centers or clusters (e.g., M or a ring center including M), M-R bonds, metal-oxygen-metal (M-O-M) bonds, and metal-hydroxyl (M-OH) bonds (e.g., provided by a reaction between any precursor and an oxygen-containing reagent, such as a counter-reactant). By removing such radiation-sensitive moieties in the deposited film, the metal center can participate in further reactions with M-OH bonds to form further M-O-M bonds within the film. As a result, the film (after post-application treatment) can include increased M-O-M bonds and decreased M-OH bonds, as compared to before post-application treatment. This hardened or densified film provides improved resistance to dissolution in the developer, while retaining a sufficient concentration of radiation-sensitive moieties.

In one embodiment, the hardened or densified film is provided by annealing in the absence of an oxygen (O)-containing gas. In some instances, annealing can include heating to a temperature at or above about 190° C. In some embodiments, annealing can be conducted under vacuum, in the presence of an inert gas (e.g., nitrogen gas (N₂), argon gas (Ar), or other non-oxidizing gas), or in the presence of an oxygen (O)-free gas, i.e., a gas free of oxygen atoms. Non-limiting examples of oxygen-free gas include O₂-free gas or H₂O-free gas. The inert gas can include one gas or a combination of inert gases. In some embodiments, a non-oxidizing gas is a gas having less than 1% of an oxygen (O)-containing gas (e.g., less than 1% of an O₂ gas). Gases can be employed at atmosphere pressure or lower.

As seen in FIG. 1C, post-application treatment of a deposited film (114) in the presence of an inert gas (103) provides a non-limiting hardened film (115) having tin-oxygen-tin (Sn—O—Sn) bonds. Both type of anneals, i.e. in the presence or in the absence of oxygen, could yield loss of the photosensitive R moiety. One non-limiting difference stems from the intermediates that would be formed: hydroxyl-rich products are formed in the presence of oxygen. However, in the absence of oxygen, hydroxyl-rich products are not formed. Rather, as seen in film (115), products rich in metal-oxide-metal are formed.

Upon exposure (104), R moieties would be cleaved to form reactive M-H moieties, which readily convert to M-OH groups in the presence of oxygen or water. Thus, the exposed areas would include additional hydrophilic groups (e.g., M-H, M-OH, and/or hydroxyl moieties) in the exposed film (116). Using positive tone development, the exposed areas can be removed because this exposed film (116) includes more soluble functional groups, such as M-OH bonds, as compared to the material (e.g., in hardened film 115) in unexposed areas that lack M-OH bonds and that are dominated by M-O-M bonds.

In another embodiment, post-application treatment includes exposure to CO₂. Use of CO₂, as seen in FIG. 1D, can provide an organometallic carbonate film having a metal carbonate (M-CO₃) bond. Thus, in another instance, the film can be further characterized as an organometallic oxycarbonate film having both M-O-M and M-CO₃ bonds. Such metal carbonate and metal oxycarbonate species can provide bonds that are more resistant to etching under wet development conditions. Post-application treatment of a non-limiting film (117) in the presence of CO₂ (105) provides a hardened film (118) having tin-carbonate-tin (Sn—CO₃—Sn) bonds. Upon exposure (106), R moieties would be cleaved to form reactive M-H moieties, which readily convert to M-OH groups in the presence of oxygen or water. Thus, the exposed areas would include additional hydrophilic groups (e.g., M-H, M-OH, and/or hydroxyl moieties) in the exposed film (119). Using positive tone development, the exposed areas are removed because the exposed film (119) includes more soluble functional groups, such as M-OH bonds, as compared to the material (e.g., in hardened film 118) in unexposed areas that lack M-OH bonds and that are dominated by M-CO₃-M bonds. In this way, use of post-application treatment (e.g., annealing in vacuum, in an inert gas, or CO₂, as well as exposing to an inert gas and/or exposing to CO₂ with heating or cooling) can tailor etch selectivity and provide a positive tone resist.

Post-application treatment in the absence of an oxygen-containing gas (e.g., with vacuum or an inert gas) or in the presence of CO₂ can employ a broad temperature range, e.g., from about 90° C. to about 350° C. Without wishing to be limited by mechanism, it is believed that thermal decomposition pathways may depend on the annealing environment. For instance, thermal cleavage of R (e.g., as in formula (I) or (II) herein) may occur at lower temperatures in an oxidizing environment, as compared to an inert environment. Accordingly, in one non-limiting embodiment, the present disclosure encompasses post-application treatment in oxygen-free environments at a broad range of temperatures, and post-application treatment in oxygen-containing environments at a lower temperature range. In some non-limiting instances, post-application treatment in an oxygen-free environment or with CO₂ is conducted at a high temperature range, e.g., from about 190° C. to about 350° C.

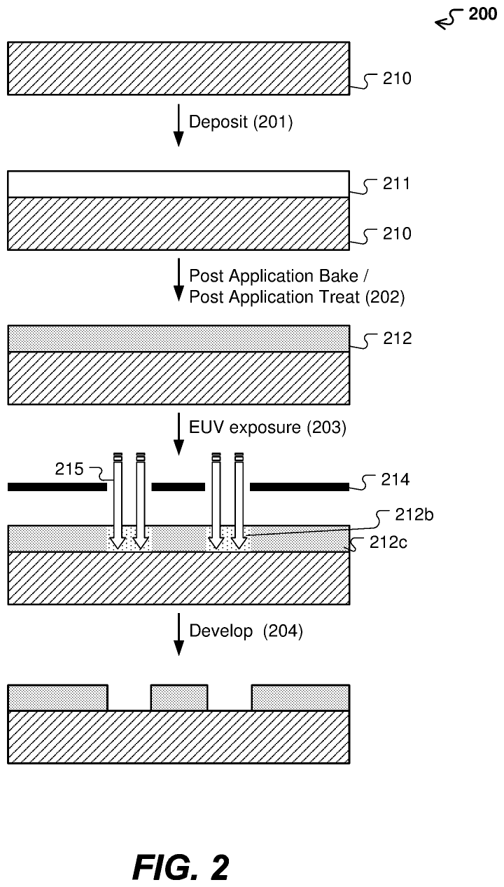

FIG. 2 provides an exemplary method 200, which includes depositing 201 a precursor as a film 211 on a top surface of a substrate 210, wherein the film 211 includes an EUV-sensitive material.

The method can further include steps to treat the deposited EUV-sensitive film. Such steps, while not required for creating the film, can be useful for using the film as a positive tone photoresist (PR). In operation 202, the method further includes post-application bake (PAB) or other post-application treatment of the deposited film 211 to provide a hardened resist film 212 that can serve as a positive tone resist. Such post-application operations can include baking in the absence of an O-containing gas, in ambient air, under vacuum, in the presence of inert gas(es), or in the presence of CO₂; as well as exposure to inert gas(es) (e.g., with heating or cooling in the presence of inert gas(es)) or exposure to CO₂ (e.g., with heating or cooling in the presence of CO₂). The hardened resist film can be characterized by the presence of M-O-M bonds and/or M-CO₃ bonds, including M-CO₃—X bonds, in which X can be M or an organic moiety. In other embodiments, the hardened resist film can be characterized by a decrease in M-OH bonds or a decrease in M-R bonds, as compared to a resist film before PAB or another post-application treatment.

Operation 203 includes patterning the film by an EUV exposure to provide an exposed film having EUV exposed areas 212b and EUV unexposed areas 212c.

Patterning can include use of a mask 214 having EUV transparent regions and EUV opaque regions, in which EUV beams 215 are transmitted through the EUV transparent region and into the film 212. EUV exposure can include, e.g., an exposure having a wavelength in the range of about 10 nm to about 20 nm in a vacuum ambient (e.g., about 13.5 nm in a vacuum ambient).

Once a pattern is provided, the method 200 can include developing 204 the film, thereby removing the EUV exposed areas 212b to provide a pattern within a positive tone resist film. Developing steps can include use of wet development processes, such as use of an alkaline development solution, an acidic development solution, an aqueous development solution, a non-aqueous development solution, or an organic development solution, as described herein.

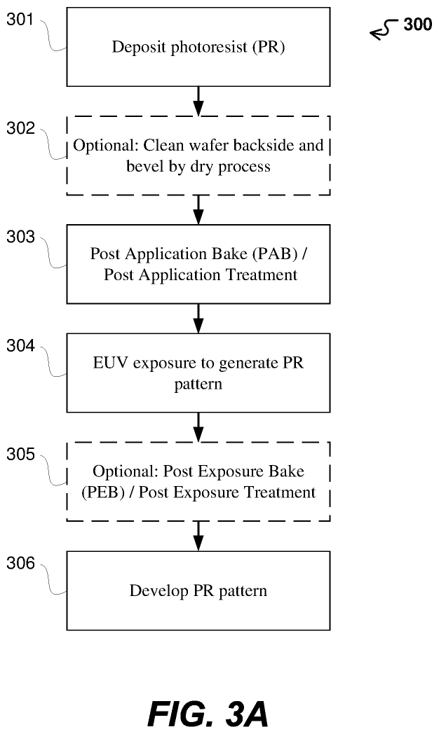

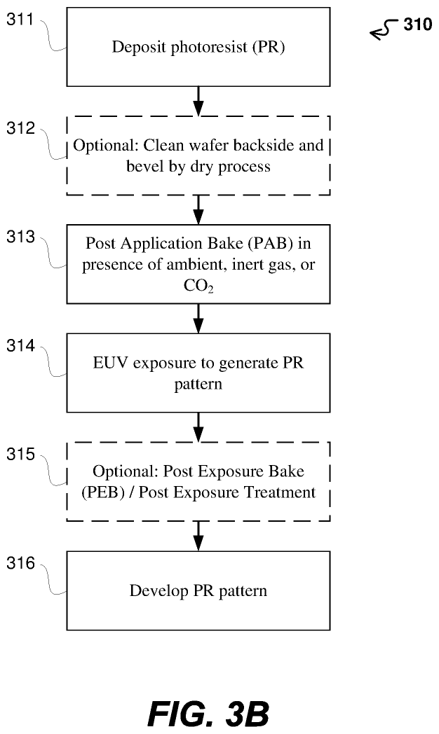

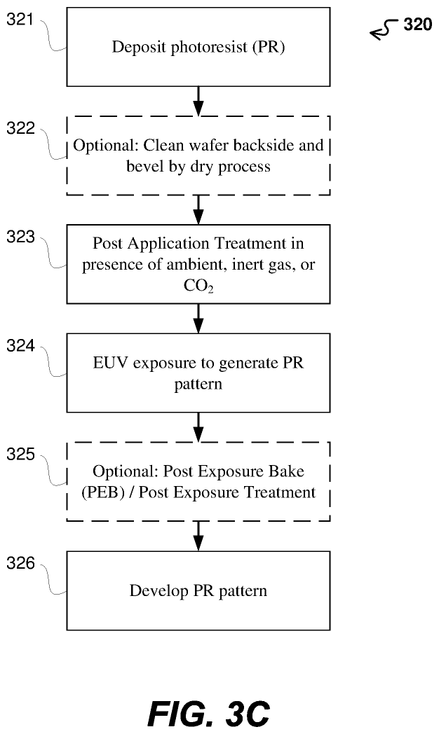

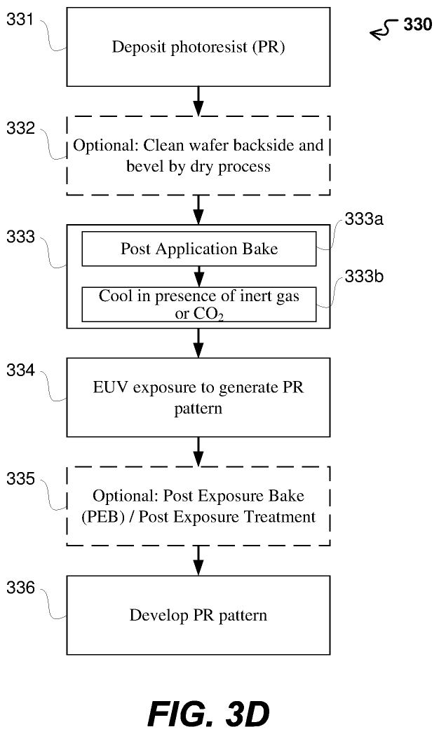

FIG. 3A provides a flow chart of an exemplary method 300 having various operations, including optional operations. Optional steps may be conducted to further modulate, modify, or treat the EUV-sensitive film(s) and/or substrate in any method herein.

As can be seen, in operation 301, a film is deposited employing a precursor with an optional counter-reactant. In optional operation 302, the backside surface or bevel of the substrate can be cleaned, and/or an edge bead of the photoresist that was deposited in the prior step can be removed. Such cleaning or removing steps can be useful for removing particles that may be present after depositing a photoresist layer. The removing step can include processing the wafer with a wet metal oxide (MeOx) edge bead removal (EBR) step.

In operation 303, post-application bake (PAB) or another post-application treatment can be performed. Such treatment can improve etch resistance of unexposed material to aqueous or non-aqueous solution. In one instance, use of PAB removes residual moisture from the layer to form a hardened resist film. The PAB can involve some combination of thermal treatment, chemical exposure, and/or moisture to increase the EUV sensitivity of the film, thereby reducing the EUV dose to develop a pattern in the film. In particular embodiments, the PAB step is conducted at a temperature greater than about 100° C. or at a temperature of from about 100° C. to about 200° C. or from about 100° C. to about 250° C. In other embodiments, the PAB step is conducted at a temperature from about 190° C. to about 350° C. in the absence of an O-containing gas. In another instance, post-application treatment includes exposing the film to an inert gas or CO₂, which can optionally include cooling or heating. Use of an inert gas can provide metal-oxygen-metal species, which can be resistant to wet-based etching. Use of CO₂ can provide metal carbonate species, which can be resistant to wet-based etching.

In operation 304, the film is exposed to EUV radiation to develop a pattern. Generally, the EUV exposure causes a change in the chemical composition of the film, creating a contrast in etch selectivity that can be used to remove a portion of the film. Such a contrast can provide a positive tone resist, as described herein. EUV exposure can include, e.g., an exposure having a wavelength in the range of about 10 nm to about 20 nm in a vacuum ambient (e.g., about 13.5 nm in a vacuum ambient).

Operation 305 is an optional post-exposure bake (PEB) of the exposed film, thereby further removing residual moisture, promoting chemical condensation within the film, or increasing contrast in etch selectivity of the exposed film; or post-treating the film in any useful manner. In one instance, the exposed film can be thermally treated (e.g., optionally in the presence of various chemical species) to promote reactivity within the EUV exposed portions of the resist upon exposure to a stripping agent or a positive tone developer (e.g., a halide-based etchant, such as HCl, HBr, H₂, Cl₂, Br₂, BCl₃, or combinations thereof, as well as any halide-based development process described herein; an aqueous alkali development solution; a non-aqueous alkali development solution; a non-aqueous development solution; or an organic development solution). In another instance, the exposed film can be thermally treated to further cross-link ligands within the EUV unexposed portions of the resist, thereby providing EUV exposed portions that can be selectively removed upon exposure to a stripping agent (e.g., a positive tone developer). In yet another instance, PEB is omitted.

Then, in operation 306, the PR pattern is developed. In various embodiments of development, the exposed regions are removed (to provide a pattern within a positive tone resist). These steps may be wet processes using one or more developers or developing solutions, followed by an optional rinse (e.g., with deionized water or another solvent). In particular embodiments, the development step is a wet process applied to the tin-based chalcogenide, tin-based oxychalcogenide, or tin-based oxycarbonate film.

In one instance, the method can include (e.g., after development) rinsing, further hardening, or baking the patterned film, thereby providing a resist mask disposed on a top surface of the substrate. Hardening steps can include any useful process to further crosslink or react the EUV unexposed or exposed areas, such as steps of exposing to plasma (e.g., O₂, O₃, Ar, He, or CO₂ plasma), exposing to ultraviolet radiation, annealing (e.g., at a temperature of about 180° C. to about 240° C.), thermal baking, or combinations thereof that can be useful for a post-development baking (PDB) step.

In one embodiment, post-application treatment can include a PAB in an ambient environment (air), in the presence of inert gas(es), or in the presence of CO₂. As seen in FIG. 3B, the method 310 includes operation 311 of depositing a precursor to form a photoresist layer, optional operation 312 for cleaning, operation 313 of performing a PAB in air, with inert gas(es), or with CO₂ to provide a hardened resist film, operation 314 for EUV exposure to provide an exposed film, optional operation 315 for PEB or other post-exposure treatment, and operation 316 of developing the exposed film.

Other post-application treatment conditions can be applied. For instance, baking (or use of heat) is not required. As seen in FIG. 3C, the method 320 includes operation 321 of depositing a precursor to form a photoresist layer, optional operation 322 for cleaning, operation 323 of performing post-application treatment with air, with inert gas(es), or with CO₂ to provide a hardened resist film, operation 324 for EUV exposure to provide an exposed film, optional operation 325 for PEB or other post-exposure treatment, and operation 326 of developing the exposed film.

Post-application treatment can include one, two, or more steps. For instance, such conditions can include PAB following by exposure to inert gas(es) or CO₂ under heating or cooling conditions. As seen in FIG. 3D, the method 330 includes operation 331 of depositing a precursor to form a photoresist layer, optional operation 332 for cleaning, operation 333 of performing a PAB 333a (with air, with inert gas(es), or with CO₂) following by cooling 333b the film in the presence of inert gas(es) or CO₂ to provide a hardened resist film, operation 334 for EUV exposure to provide an exposed film, optional operation 335 for PEB or other post-exposure treatment, and operation 336 of developing the exposed film. Alternatively, an operation for hardening can include performing a PAB (with air, with inert gas(es), or with CO₂), followed by further heating in the presence of inert gas(es) or CO₂.

Any useful type of chemistry can be employed during the depositing, patterning, and/or developing steps. Such steps may be based on dry processes employing chemistry in a gaseous phase or wet processes employing chemistry in a wet phase. Various embodiments include combining dry operations of film formation by vapor deposition and (EUV) lithographic photopatterning with wet development operations.

In one non-limiting embodiment, a process of positive tone development to form a pattern or resist mask can be conducted as follows:

Dry depositing, for example by CVD, an organometallic oxide film, such as depicted in FIG. 1A, for example a 20 nm thick photopatternable metal oxide EUV resist imaging layer on a 300 mm wafer with a 45 nm underlayer (e.g., spin-on carbon (SOC) underlayer);

Performing a post-application (deposition) bake (PAB) between 100° C. and 200° C. or even above 200° C., such as from 100° C. to 250° C. or 100° C. to 350° C. In another instance, the PAB can be from 180° C. to 250° C. or 100° C. to 350° C. for about 30 seconds (s) to 2 minutes (min) or from 10 s to 5 min (e.g., with ambient air, inert gas(es), or CO₂). While this disclosure is not limited by any particular theory of operation, it is understood that the PAB may effectively harden the unexposed regions of the resist film by crosslinking M-OH groups to form M-O-M bonds, in which M is the metal within the film. In some non-limiting instances, omitting a post-exposure bake (PEB) retains reactive M-H and M-OH functionality resulting from EUV induced cleavage of alkyl groups. This material is more readily etched by a standard aqueous based developer (e.g., TMAH, as described further below), since the removal of hydrophobic isopropyl groups by EUV induced cleavage can drive selective interaction/reaction of the aqueous alkaline developer with the exposed material to give positive tone development;

Performing EUV exposure, optionally omitting any post-exposure bake (PEB), but other instance may benefit from including a PEB to enhance etch selectivity; and

Performing positive tone wet development. A suitable positive tone wet development may be conducted with minimal (e.g., less than 1 hour) delay using an aqueous base developer, such a tetramethylammonium hydroxide (TMAH), 2.3-2.5 (e.g., 2.38) wt. % solution, with subsequent deionized (DI) water rinse. Such an aqueous alkaline developer solution is currently employed for organic spin-on EUV photoresists, so it can be readily implemented on established resist processing tracks. Yet, in other embodiments, depending on the impact of some high-temperature gas treatments, other positive tone development processes may be used. In some instance, the developer can include other aqueous solvents, such as aqueous acids or even DI water. Additional non-limiting developers are described herein.

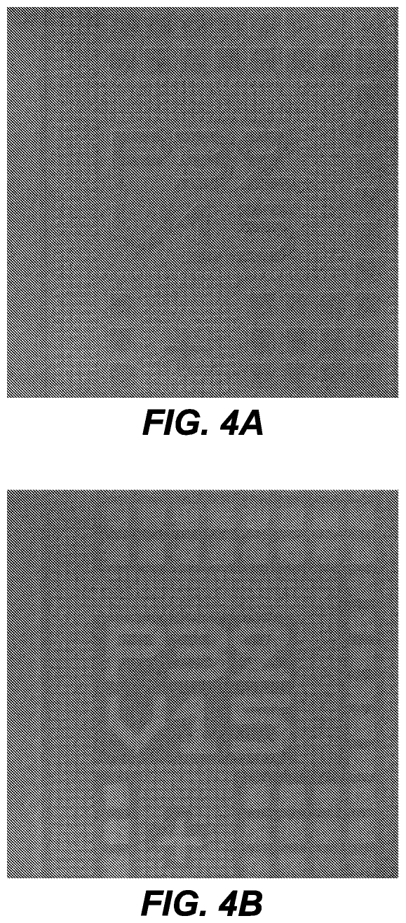

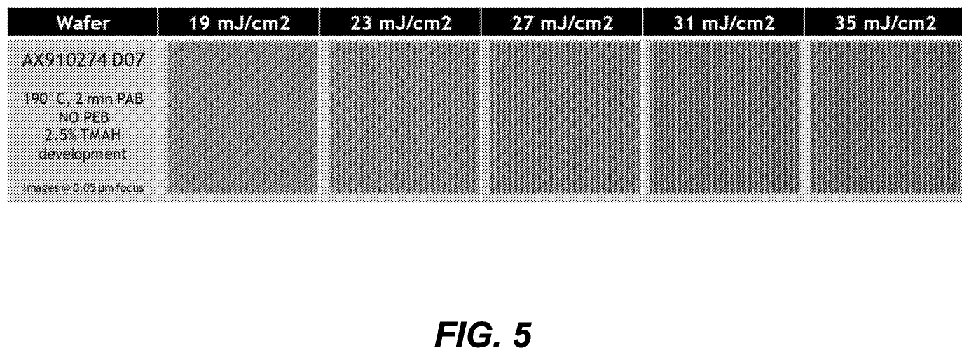

One non-limiting process can include the following:
1. Deposit metal oxide resist film;
2. Edge bead removal (removing resist from edge);
3. Post-application bake (PAB) at 190° for 2 min;
4. Exposure to EUV light source;
5. Optional post-exposure bake (PEB), which can be omitted in some instances;
6. Positive development (removal of exposed resist in 2.5 wt. % tetramethylammonium hydroxide (TMAH);
   a. Prewet (5 s);
   b. TMAH exposure (30 s);
   c. DI Rinse (30 s);
   d. Spin dry (60 s); and
7. Wafer inspection.
   FIG. 4A-4B provides SEM images of resist films produced by using (A) a negative tone development process with a ketone or (B) a positive tone development process with aqueous TMAH. Further results are depicted in FIG. 5, where it can be seen that positive tone development of the dry deposited EUV resist films was successful. Based on these data, this appears to be possible at lower EUV exposure doses than those required for negative tone imaging.

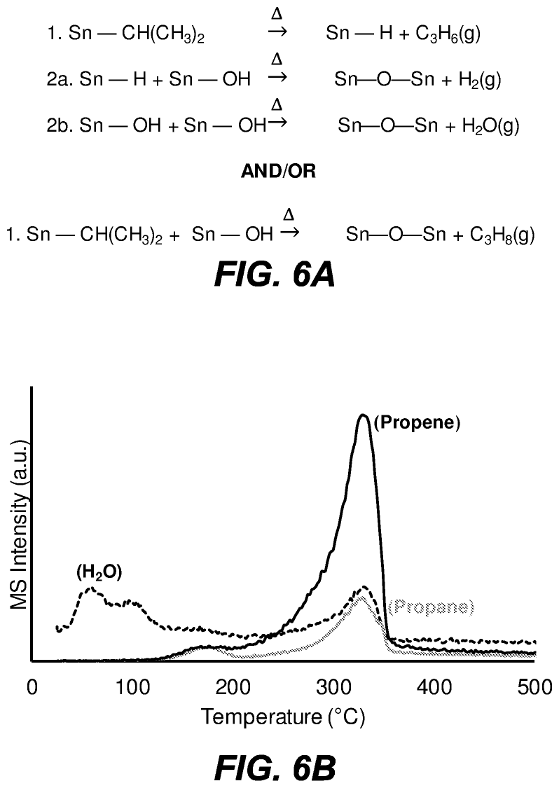

In particular embodiments, the non-limiting precursor includes a tin (Sn) metal center and isopropyl (i-Pr) as the radiation-sensitive moiety. Without wishing to be limited by mechanism, FIG. 6A provides reaction schemes of a post-application treatment including high temperature PAB followed by subsequent cooling under N₂ to condense films in a way that yields a low OH concentration. In particular, PAB results in thermal cleavage of some i-Pr groups to provide a reactive intermediate that can further react to form metal-oxygen-metal bonds and, thus, provide a higher molecular weight material. FIG. 6B provides analysis of the release of the i-Pr group (as propene or propane) from the film as a function of temperature. The desorption spectra show thermal-induced cleavage of i-Pr ligands under UHV/inert conditions between 150° C. and 350° C.

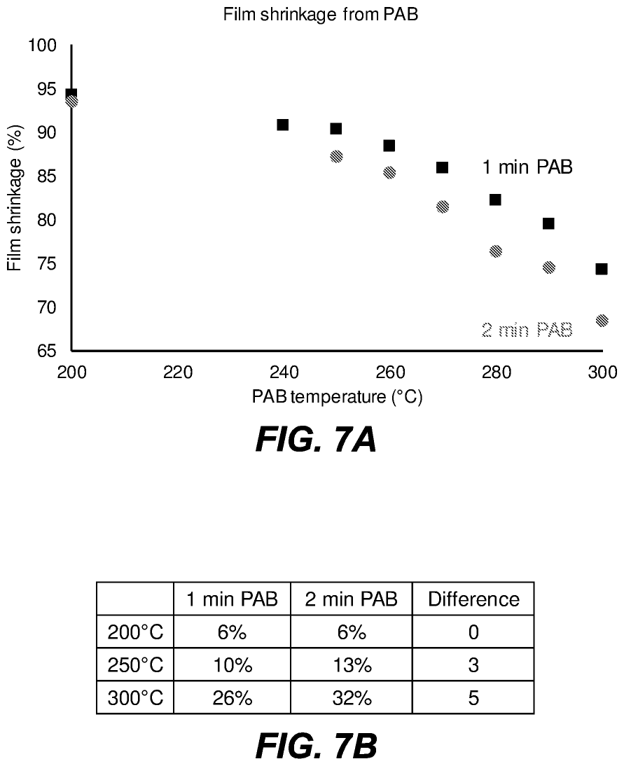

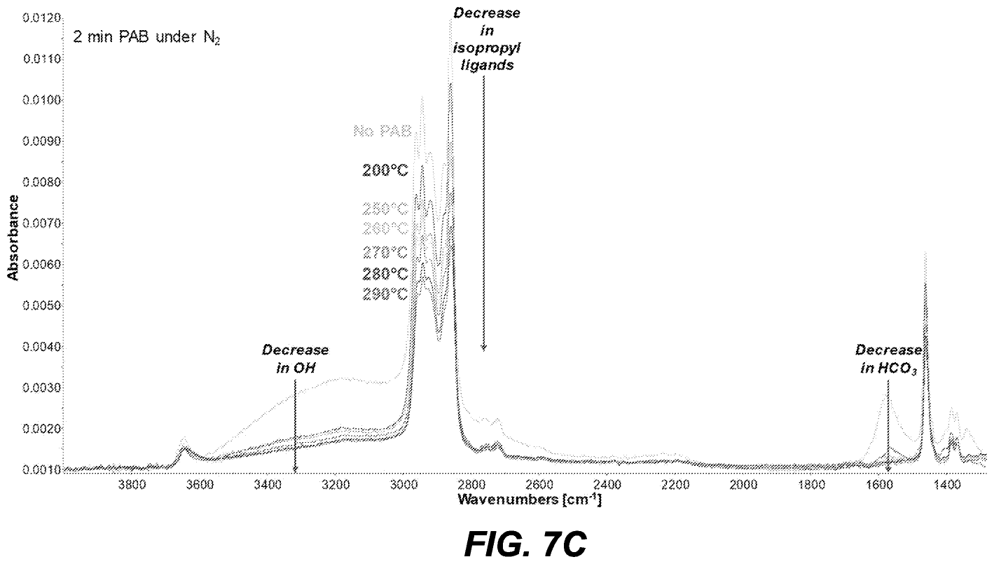

The hardened or condensed films can be monitored by assessing film shrinkage before and after PAB using ellipsometry. As seen in FIG. 7A-7B, film shrinkage increased as temperature of the PAB was increased. In addition, as the temperature of the PAB increases, the difference in film shrinkage between 1 and 2 min PAB increases. FIG. 7C provides IR analysis of films for PAB using various temperatures under N₂ for a period of 2 min.

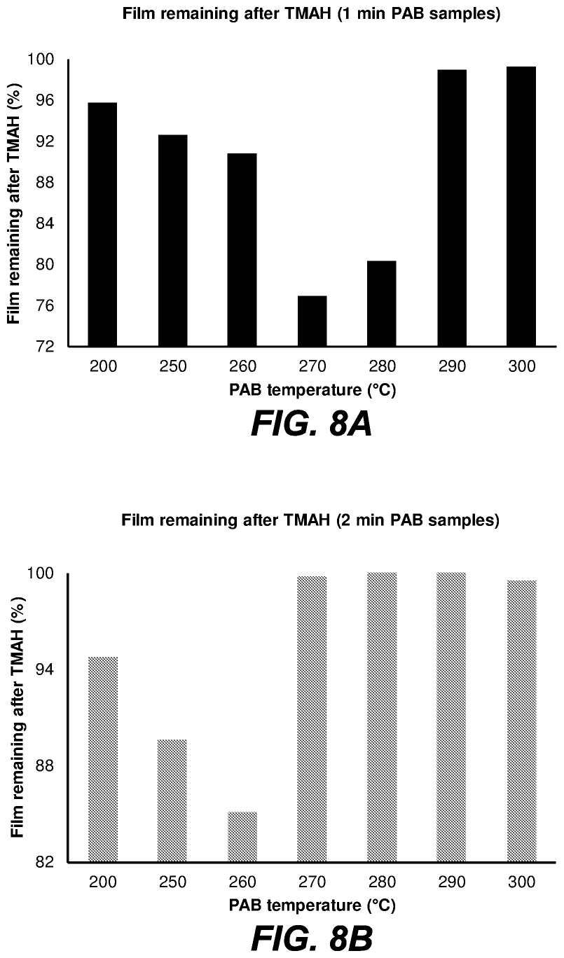

Hardened or condensed films were also treated with TMAH. As seen in FIG. 8A-8B, certain post-application treatment conditions provided films having resistance to etching by TMAH. Treatment conditions included PAB of a deposited film for 1 min (FIG. 8A) or 2 min (FIG. 8B). As can be seen, resistance to TMAH first worsened and then improved. At a first temperature range (from 200° C. to 270° C.), the initial trend shows increasing etch rates in the TMAH developer and thus increasing film-loss during development. This is likely due to loss of i-Pr ligands and inhibited condensation from steric hindrance of moieties still bound to the precursor's metal center. At a second temperature range (from 270° C. to 300° C.), a second trend is observed, in which film loss is minimized. Without wishing to be limited by mechanism, once sufficient amount of i-Pr ligands are thermally cleaved, condensation can occur due to lower steric hindrance. As seen in FIG. 8B, the onset for TMAH resistance occurs at lower temperatures with a prolonged PAB time. In this non-limiting instance, loss of about 30% of the i-Pr ligands provided a hardened or condensed film exhibiting resistance to etching by a wet development process.

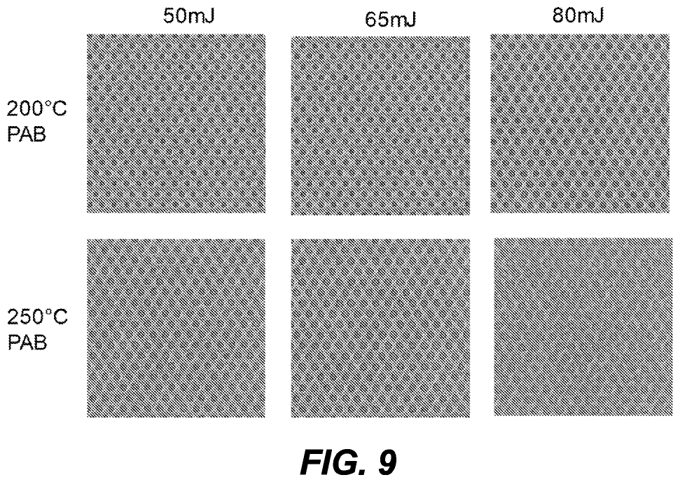

FIG. 9 provides SEM images of resist films produced by using post-application treatment (PAB under N₂ for 1 min at either 200° C. in upper images or 250° C. in lower images) and developed using a wet development process (2.38 wt. % TMAH). Deposited films were a 25 nm thick photopatternable metal oxide EUV resist imaging layer with a 10 nm underlayer (e.g., spin-on glass (SOG) underlayer). Development occurred immediately after EUV exposure.

Accordingly, it has been demonstrated that high performance dry deposited EUV photoresist material can be effectively patterned to give either negative or positive tone images. This could also enable the application of novel process flows involving a first EUV exposure, followed by positive tone development; then a second EUV exposure, followed by negative tone development, or vice versa.

### Precursors

The layers and films herein may include an element (e.g., a metal atom or a non-metal atom) having a high photoabsorption cross-section, such as equal to or greater than 1×10⁷ cm²/mol. Such elements can be provided by depositing one or more precursor(s).

In some embodiments, the film is a radiation-sensitive film (e.g., an EUV-sensitive film). This film, in turn, can serve as an EUV resist, as further described herein. In particular embodiments, the layer or film can include one or more ligands (e.g., EUV labile ligands) that can be removed, cleaved, or cross-linked by radiation (e.g., EUV or DUV radiation).

The precursor can provide a patternable film that is sensitive to radiation (or a patterning radiation-sensitive film or a photopatternable film). Such radiation can include EUV radiation, DUV radiation, or UV radiation that is provided by irradiating through a patterned mask, thereby being a patterned radiation. The film itself can be altered by being exposed to such radiation, such that the film is radiation-sensitive or photosensitive. In particular embodiments, the precursor is an organometallic compound, which includes at least one metal center. In other embodiments, the film obtained from the precursor is characterized by a Beer's absorption coefficient α of more than about 6 μm⁻¹ (e.g., more than about 7 μm⁻¹, 8 μm⁻¹, 9 μm⁻¹, 10 μm⁻¹, 20 μm⁻¹, 30 μm⁻¹, or more) at the wavelength of the patterned radiation being exposed to the film (e.g., from UV, DUV, or EUV exposure).

The precursor can have any useful number and type of ligand(s). In some embodiments, the ligand can be characterized by its ability to react in the presence of a counter-reactant, or in the presence of patterned radiation. For instance, the precursor can include a ligand that reacts with a counter-reactant, which can introduce linkages between metal centers (e.g., an —O— linkage). In another instance, the precursor can include a ligand that eliminates in the presence of patterned radiation. Such an EUV labile ligand can include branched or linear alkyl groups having a beta-hydrogen, as well as any described herein for R in formula (I) or (II).

Other EUV labile ligands include alkyl, alkenyl, or alkynyl groups, which can be branched or linear. Yet other EUV labile ligands include aryl groups, such as those having one, two, or three rings. Such alkyl, alkenyl, alkynyl, and aryl groups can be substituted with one or more halos (e.g., one or more fluoro). Non-limiting labile ligands include optionally substituted C₁₋₁₂ alkyl, optionally substituted C₂₋₁₂ alkenyl, optionally substituted C₂₋₁₂ alkynyl, optionally substituted C₁₋₁₂ haloalkyl, optionally substituted C₂₋₁₂ haloalkenyl, optionally substituted C₂₋₁₂ haloalkynyl, optionally substituted aryl, or optionally substituted haloaryl.

The precursor can be any useful metal-containing precursor, such as an organometallic agent, a metal halide, or a capping agent (e.g., as described herein). In a non-limiting instance, the precursor includes a structure having formula (I):

MₐR_{b} (I),

wherein:
M is a metal or an atom having a high EUV absorption cross-section;
each R is, independently, H, halo, optionally substituted alkyl, optionally substituted cycloalkyl, optionally substituted cycloalkenyl, optionally substituted alkenyl, optionally substituted alkynyl, optionally substituted alkoxy, optionally substituted alkanoyloxy, optionally substituted aryl, optionally substituted amino, optionally substituted bis(trialkylsilyl)amino, optionally substituted trialkylsilyl, oxo, an anionic ligand, a neutral ligand, or a multidentate ligand;
a≥1; and b≥1.

In another non-limiting instance, the precursor includes a structure having formula (II):

MₐR_{b}L_{c} (II),

wherein:
M is a metal or an atom having a high EUV absorption cross-section;
each R is, independently, halo, optionally substituted alkyl, optionally substituted aryl, optionally substituted amino, optionally substituted alkoxy, or L;
each L is, independently, a ligand, an anionic ligand, a neutral ligand, a multidentate ligand, ion, or other moiety that is reactive with a counter-reactant, in which R and L with M, taken together, can optionally form a heterocyclyl group or in which R and L, taken together, can optionally form a heterocyclyl group;
a≥1; b≥1; and c≥1.

In some embodiments, each ligand within the precursor can be one that is reactive with a counter-reactant. In one instance, the precursor includes a structure having formula (II), in which each R is, independently, L. In another instance, the precursor includes a structure having formula (IIa):

MₐL_{c} (IIa),

wherein:
M is a metal or an atom having a high EUV absorption cross-section;
each L is, independently, a ligand, ion, or other moiety that is reactive with a counter-reactant, in which two L, taken together, can optionally form a heterocyclyl group;
a≥1; and c≥1.
   In particular embodiments of formula (IIa), a is 1. In further embodiments, c is 2, 3, or 4.

For any formula herein, M can be a metal or a metalloid or an atom with a high patterning radiation-absorption cross-section (e.g., an EUV absorption cross-section that is equal to or greater than 1×10⁷ cm²/mol). In some embodiments, M is tin (Sn), bismuth (Bi), tellurium (Te), cesium (Cs), antimony (Sb), indium (In), molybdenum (Mo), hafnium (Hf), iodine (I), zirconium (Zr), iron (Fe), cobalt (Co), nickel (Ni), copper (Cu), zinc (Zn), silver (Ag), platinum (Pt), and lead (Pb). In further embodiments, M is Sn, a is 1, and c is 4 in formula (I), (II), or (IIa). In other embodiments, M is Sn, a is 1, and c is 2 in formula (I), (II), or (IIa). In particular embodiments, M is Sn(II) (e.g., in formula (I), (II), or (IIa)), thereby providing a precursor that is a Sn(II)-based compound. In other embodiments, M is Sn(IV) (e.g., in formula (I), (II), or (IIa)), thereby providing a precursor that is a Sn(IV)-based compound. In particular embodiments, the precursor includes iodine (e.g., as in periodate).

For any formula herein, each R is, independently, H, halo, optionally substituted alkyl, optionally substituted cycloalkyl, optionally substituted cycloalkenyl, optionally substituted alkenyl, optionally substituted alkynyl, optionally substituted alkoxy (e.g., —OR¹, in which R¹ can be optionally substituted alkyl), optionally substituted alkanoyloxy, optionally substituted aryl, optionally substituted amino, optionally substituted bis(trialkylsilyl)amino, optionally substituted trialkylsilyl, oxo, an anionic ligand (e.g., oxido, chlorido, hydrido, acetate, iminodiacetate, propanoate, butanoate, benzoate, etc.), a neutral ligand, or a multidentate ligand.

In some embodiments, the optionally substituted amino is —NR¹R², in which each R¹ and R² is, independently, H or alkyl; or in which R¹ and R², taken together with the nitrogen atom to which each are attached, form a heterocyclyl group, as defined herein. In other embodiments, the optionally substituted bis(trialkylsilyl)amino is —N(SiR¹R²R³)₂, in which each R¹, R², and R³ is, independently, optionally substituted alkyl. In yet other embodiments, the optionally substituted trialkylsilyl is —SiR¹R²R³, in which each R¹, R², and R³ is, independently, optionally substituted alkyl.

In other embodiments, the formula includes a first R (or first L) that is —NR ¹R² and a second R (or second L) that is —NR¹R², in which each R¹ and R² is, independently, H or optionally substituted alkyl; or in which R¹ from a first R (or first L) and R¹ from a second R (or second L), taken together with the nitrogen atom and the metal atom to which each are attached, form a heterocyclyl group, as defined herein. In yet other embodiments, the formula includes a first R that is —OR¹ and a second R that is —OR¹, in which each R¹ is, independently, H or optionally substituted alkyl; or in which R¹ from a first R and R¹ from a second R, taken together with the oxygen atom and the metal atom to which each are attached, form a heterocyclyl group, as defined herein.

In some embodiments, at least one of R or L (e.g., in formula (I), (II), or (IIa)) is optionally substituted alkyl. Non-limiting alkyl groups include, e.g., CₙH₂ₙ₊₁, where n is 1, 2, 3, or greater, such as methyl, ethyl, n-propyl, isopropyl, n-butyl, isobutyl, s-butyl, or t-butyl. In various embodiments, R or L has at least one beta-hydrogen, beta-halogen, or beta-fluorine. In other embodiments, at least one of R or L is a halo-substituted alkyl (e.g., a fluoro-substituted alkyl).

In some embodiments, each R or L or at least one R or L (e.g., in formula (I), (II), or (IIa)) is halo. In particular, the precursor can be a metal halide. Non-limiting metal halides include SnBr₄, SnCl₄, SnI₄, and SbCl₃.

In some embodiments, each R or L or at least one R or L (e.g., in formula (I), (II), or (IIa)) can include a nitrogen atom. In particular embodiments, one or more R or L can be optionally substituted amino, an optionally substituted monoalkylamino (e.g., —NR¹H, in which R¹ is optionally substituted alkyl), an optionally substituted dialkylamino (e.g., —NR¹R², in which each R¹ and R² is, independently, optionally substituted alkyl), or optionally substituted bis(trialkylsilyl)amino. Non-limiting R and L substituents can include, e.g., —NMe₂, —NHMe, -NEt₂, —NHEt, —NMeEt, —N(t-Bu)-[CHCH₃]₂—N(t-Bu)-(tbba), —N(SiMe₃)₂, and —N(SiEt₃)₂.

In some embodiments, each R or L or at least one R or L (e.g., in formula (I), (II), or (IIa)) can include a silicon atom. In particular embodiments, one or more R or L can be optionally substituted trialkylsilyl or optionally substituted bis(trialkylsilyl)amino. Non-limiting R or L substituents can include, e.g., —SiMe₃, —SiEt₃, —N(SiMe₃)₂, and —N(SiEt₃)₂.

In some embodiments, each R or L or at least one R or L (e.g., in formula (I), (II), or (IIa)) can include an oxygen atom. In particular embodiments, one or more R or L can be optionally substituted alkoxy or optionally substituted alkanoyloxy. Non-limiting R or L substituents include, e.g., methoxy, ethoxy, isopropoxy (i-PrO), t-butoxy (t-BuO), acetate (—OC(O)—CH₃), and —O═C(CH₃)—CH═C(CH₃)—O— (acac).

Any formulas herein can include one or more neutral ligands. Non-limiting neutral ligands include an optionally substituted amine (e.g., NR₃ or R₂N-Ak-NR₂, in which each R can be, independently, H, optionally substituted alkyl, optionally substituted hydrocarbyl, or optionally substituted aryl, and Ak is optionally substituted alkylene), an optionally substituted phosphine (e.g., PR₃ or R₂P-Ak-PR₂, in which each R can be, independently, H, optionally substituted alkyl, optionally substituted hydrocarbyl, or optionally substituted aryl, and Ak is optionally substituted alkylene), an optionally substituted ether (e.g., OR₂, in which each R can be, independently, H, optionally substituted alkyl, optionally substituted hydrocarbyl, or optionally substituted aryl), an optionally substituted alkyl, an optionally substituted alkene, an optionally substituted alkyne, an optionally substituted benzene, oxo, or carbon monoxide.

Any formulas herein can include one or more multidentate (e.g., bidentate) ligands. Non-limiting multidentate ligand include a diketonate (e.g., acetylacetonate (acac) or —OC(R¹)-Ak-(R¹)CO— or —OC(R¹)—C(R²)—(R¹)CO—), a bidentate chelating dinitrogen (e.g., —N(R¹)-Ak-N(R¹)— or —N(R³)—CR⁴—CR²═N(R¹)—), an aromatic (e.g., —Ar—), an amidinate (e.g., —N(R¹)—C(R²)—N(R¹)—), an aminoalkoxide (e.g., —N(R¹)-Ak-O— or —N(R¹)₂-Ak-O—), a diazadienyl (e.g., —N(R¹)—C(R²)—C(R²)—N(R¹)—), a cyclopentadienyl, a pyrazolate, an optionally substituted heterocyclyl, an optionally substituted alkylene, or an optionally substituted heteroalkylene. In particular embodiments, each R¹ is, independently, H, optionally substituted alkyl, optionally substituted haloalkyl, or optionally substituted aryl; each R² is, independently, H or optionally substituted alkyl; R³ and R⁴, taken together, forms an optionally substituted heterocyclyl; Ak is optionally substituted alkylene; and Ar is optionally substituted arylene.

In particular embodiments, the precursor includes tin. In some embodiments, the tin precursor includes SnR or SnR₂ or SnR₄ or R₃SnSnR₃, wherein each R is, independently, H, halo, optionally substituted C₁₋₁₂ alkyl, optionally substituted C₁₋₁₂ alkoxy, optionally substituted amino (e.g., —NR¹R²), optionally substituted C₂₋₁₂ alkenyl, optionally substituted C₂₋₁₂ alkynyl, optionally substituted C₃₋₈ cycloalkyl, optionally substituted aryl, cyclopentadienyl, optionally substituted bis(trialkylsilyl)amino (e.g., —N(SiR¹R²R³)₂), optionally substituted alkanoyloxy (e.g., acetate), a diketonate (e.g., —OC(R′)-Ak-(R²)CO—), or a bidentate chelating dinitrogen (e.g., —N(R′)-Ak-N(R′)—). In particular embodiments, each R¹, R², and R³ is, independently, H or C₁₋₁₂ alkyl (e.g., methyl, ethyl, isopropyl, t-butyl, or neopentyl); and Ak is optionally substituted C₁₋₆ alkylene. In particular embodiments, each R is, independently, halo, optionally substituted C₁₋₁₂ alkoxy, optionally substituted amino, optionally substituted aryl, cyclopentadienyl, or a diketonate. Non-limiting tin precursors include SnF₂, SnH₄, SnBr₄, SnCl₄, SnI₄, tetramethyl tin (SnMe₄), tetraethyl tin (SnEt₄), trimethyl tin chloride (SnMe₃Cl), dimethyl tin dichloride (SnMe₂Cl₂), methyl tin trichloride (SnMeCl₃), tetraallyltin, tetravinyl tin, hexaphenyl ditin (IV) (Ph₃Sn—SnPh₃, in which Ph is phenyl), dibutyldiphenyltin (SnBu₂Ph₂), trimethyl(phenyl) tin (SnMe₃Ph), trimethyl(phenylethynyl) tin, tricyclohexyl tin hydride, tributyl tin hydride (SnBu₃H), dibutyltin diacetate (SnBu₂(CH₃COO)₂), tin(II) acetylacetonate (Sn(acac)₂), SnBu₃(OEt), SnBu₂(OMe)₂, SnBu₃(OMe), Sn(t-BuO)₄, Sn(n-Bu)(t-BuO)₃, tetrakis(dimethylamino)tin (Sn(NMe₂)₄), tetrakis(ethylmethylamino)tin (Sn(NMeEt)₄), tetrakis(diethylamino)tin(IV) (Sn(NEt₂)₄), (dimethylamino)trimethyl tin(IV) (Sn(Me)₃(NMe₂), Sn(i-Pr)(NMe₂)₃, Sn(n-Bu)(NMe₂)₃, Sn(s-Bu)(NMe₂)₃, Sn(i-Bu)(NMe₂)₃, Sn(t-Bu)(NMe₂)₃, Sn(t-Bu)₂(NMe₂)₂, Sn(t-Bu)(NEt₂)₃, Sn(tbba), Sn(II) (1,3-bis(1,1-dimethylethyl)-4,5-dimethyl-(4R,5R)-1,3,2-diazastannolidin-2-ylidene), or bis[bis(trimethylsilyl)amino] tin (Sn[N(SiMe₃)₂]₂).

In other embodiments, the precursor includes bismuth, such as in BiR₃, wherein each R is, independently, halo, optionally substituted C₁₋₁₂ alkyl, mono-C₁₋₁₂ alkylamino (e.g., —NR¹H), di-C₁₋₁₂ alkylamino (e.g., —NR¹R²), optionally substituted aryl, optionally substituted bis(trialkylsilyl)amino (e.g., —N(SiR¹R²R³)₂), or a diketonate (e.g., —OC(R⁴)-Ak-(R⁵)CO—). In particular embodiments, each R¹, R², and R³ is, independently, C₁₋₁₂ alkyl (e.g., methyl, ethyl, isopropyl, t-butyl, or neopentyl); and each R⁴ and R⁵ is, independently, H or optionally substituted C₁₋₁₂ alkyl (e.g., methyl, ethyl, isopropyl, t-butyl, or neopentyl). Non-limiting bismuth precursors include BiCl₃, BiMe₃, BiPh₃, Bi(NMe₂)₃, Bi[N(SiMe₃)₂]₃, and Bi(thd)₃, in which thd is 2,2,6,6-tetramethyl-3,5-heptanedionate.

In other embodiments, the precursor includes tellurium, such as TeR₂ or TeR₄, wherein each R is, independently, halo, optionally substituted C₁₋₁₂ alkyl (e.g., methyl, ethyl, isopropyl, t-butyl, and neopentyl), optionally substituted C₁₋₁₂ alkoxy, optionally substituted aryl, hydroxyl, oxo, or optionally substituted trialkylsilyl. Non-limiting tellurium precursors include dimethyl tellurium (TeMe₂), diethyl tellurium (TeEt₂), di(n-butyl) tellurium (Te(n-Bu)₂), di(isopropyl) tellurium (Te(i-Pr)₂), di(t-butyl) tellurium (Te(t-Bu)₂), t-butyl tellurium hydride (Te(t-Bu)(H)), Te(OEt)₄, bis(trimethylsilyl)tellurium (Te(SiMe₃)₂), and bis(triethylsilyl) tellurium (Te(SiEt₃)₂).

The precursor can include antimony, such as in SbR₃, wherein each R is, independently, halo, optionally substituted C₁₋₁₂ alkyl (e.g., methyl, ethyl, isopropyl, t-butyl, and neopentyl), optionally substituted C₁₋₁₂ alkoxy, or optionally substituted amino (e.g., —NR¹R², in which each R¹ and R² is, independently, H or optionally substituted C₁₋₁₂ alkyl). Non-limiting antimony precursors include SbCl₃, Sb(OEt)₃, Sb(On-Bu)₃, and Sb(NMe₂)₃.

Other precursors include indium precursors, such as in InR₃, wherein each R is, independently, halo, optionally substituted C₁₋₁₂ alkyl (e.g., methyl, ethyl, isopropyl, t-butyl, and neopentyl), or a diketonate (e.g., —OC(R⁴)-Ak-(R⁵)CO—, in which each R⁴ and R⁵ is, independently, H or C₁₋₁₂ alkyl). Non-limiting indium precursors include InCp, in which Cp is cyclopentadienyl, InCl₃, InMe₃, In(acac)₃, In(CF₃COCHCOCH₃)₃, and In(thd)₃.

The precursor can include iodine, such as RI, wherein R is iodo (I) or optionally substituted C₁₋₁₂ alkyl, or periodate. Non-limiting iodine precursors include iodine gas (I₂), diiodomethane (CH₂I₂), and periodate.

Yet other precursors and non-limiting substituents are described herein. For instance, precursors can be any having a structure of formulas (I), (II), and (IIa), as described above; or formulas (III), (IV), (V), (VI), (VII), or (VIII), as described below. Any of the substituents M, R, X, or L, as described herein, can be employed in any of formulas (I), (II), (IIa), (III), (IV), (V), (VI), (VII), or (VIII).

Furthermore, two or more different precursors can be employed within each layer (e.g., a film). For instance, two or more of any metal-containing precursors herein can be employed to form an alloy. In one non-limiting instance, tin telluride can be formed by employing tin precursor including an —NR₂ ligand with RTeH, RTeD, or TeR₂ precursors, in which R is an alkyl, particularly t-butyl or i-propyl. In another instance, a metal telluride can be formed by using a first precursor including an alkoxy or a halo ligand (e.g., SbCl₃) with a tellurium-containing precursor including a trialkylsilyl ligand (e.g., bis(trimethylsilyl)tellurium).

Yet other exemplary EUV-sensitive materials, as well as processing methods and apparatuses, are described in U.S. Pat. No. 9,996,004; Int. Pat. Pub. No. WO 2020/102085; and Int. Pat. Pub. No. WO 2019/217749, each of which is incorporated herein by reference in its entirety.

As described herein, the films, layers, and methods herein can be employed with any useful precursor. In some instances, the precursor includes a metal halide having the following formula (III):

MXₙ (III),

in which M is a metal, X is halo, and n is 2 to 4, depending on the selection of M. Exemplary metals for M include Sn, Te, Bi, or Sb. Exemplary metal halides include SnBr₄, SnCl₄, SnI₄, and SbCl₃.

Another non-limiting precursor includes a structure having formula (IV):

MRₙ (IV),

in which M is a metal; each R is independently H, an optionally substituted alkyl, amino (e.g., —NR₂, in which each R is independently alkyl), optionally substituted bis(trialkylsilyl)amino (e.g., —N(SiR₃)₂, in which each R is independently alkyl), or an optionally substituted trialkylsilyl (e.g., —SiR₃, in which each R is independently alkyl); and n is 2 to 4, depending on the selection of M. Exemplary metals for M include Sn, Te, Bi, or Sb. The alkyl group may be CₙH₂ₙ₊₁, where n is 1, 2, 3, or greater. Exemplary organometallic agents include SnMe₄, SnEt₄, TeRₙ, RTeR, t-butyl tellurium hydride (Te(t-Bu)(H)), dimethyl tellurium (TeMe₂), di(t-butyl) tellurium (Te(t-Bu)₂), di(isopropyl)tellurium (Te(i-Pr)₂), bis(trimethylsilyl)tellurium (Te(SiMe₃)₂), bis(triethylsilyl) tellurium (Te(SiEt₃)₂), tris(bis(trimethylsilyl)amido) bismuth (Bi[N(SiMe₃)₂]₃), Sb(NMe₂)₃, and the like.

Another non-limiting precursor can include a capping agent having the following formula (V):

MLₙ (V),

in which M is a metal; each L is independently an optionally substituted alkyl, amino (e.g., —NR¹R², in which each of R¹ and R² can be H or alkyl, such as any described herein), alkoxy (e.g., —OR, in which R is alkyl, such as any described herein), halo, or other organic substituent; and n is 2 to 4, depending on the selection of M. Exemplary metals for M include Sn, Te, Bi, or Sb. Exemplary ligands include dialkylamino (e.g., dimethylamino, methylethylamino, and diethylamino), alkoxy (e.g., t-butoxy and isopropoxy), halo (e.g., F, Cl, Br, and I), or other organic substituents (e.g., acetylacetone or N²,N³-di-tertbutyl-butane-2,3-diamino). Non-limiting capping agents include SnCl₄; SnI₄; Sn(NR₂)₄, wherein each of R is independently methyl or ethyl; or Sn(t-BuO)₄. In some embodiments, multiple types of ligands are present.

A precursor can include a hydrocarbyl-substituted capping agent having the following formula (VI):

RₙMXₘ (VI),

wherein M is a metal, R is a C₂₋₁₀ alkyl or substituted alkyl having a beta-hydrogen, and X is a suitable leaving group upon reaction with a hydroxyl group of the exposed hydroxyl groups. In various embodiments, n=1 to 3, and m=4−n, 3−n, or 2−n, so long as m>0 (or m≥1). For example, R may be t-butyl, t-pentyl, t-hexyl, cyclohexyl, isopropyl, isobutyl, sec-butyl, n-butyl, n-pentyl, n-hexyl, or derivatives thereof having a heteroatom substituent in the beta position. Suitable heteroatoms include halogen (F, Cl, Br, or I), or oxygen (—OH or —OR). X may be dialkylamino (e.g., dimethylamino, methylethylamino, or diethylamino), alkoxy (e.g., t-butoxy, isopropoxy), halo (e.g., F, Cl, Br, or I), or another organic ligand. Examples of hydrocarbyl-substituted capping agents include t-butyltris(dimethylamino)tin (Sn(t-Bu)(NMe₂)₃), n-butyltris(dimethylamino)tin (Sn(n-Bu)(NMe₂)₃), t-butyltris(diethylamino)tin (Sn(t-Bu)(NEt₂)₃), di(t-butyl)di(dimethylamino)tin (Sn(t-Bu)₂(NMe₂)₂), sec-butyltris(dimethylamino)tin (Sn(s-Bu)(NMe₂)₃), n-pentyltris(dimethylamino)tin (Sn(n-pentyl)(NMe₂)₃), i-butyltris(dimethylamino) tin (Sn(i-Bu)(NMe₂)₃), i-propyltris(dimethylamino)tin (Sn(i-Pr)(NMe₂)₃), t-butyltris(t-butoxy)tin (Sn(t-Bu)(t-BuO)₃), n-butyl(tris(t-butoxy)tin (Sn(n-Bu)(t-BuO)₃), or isopropyltris(t-butoxy)tin (Sn(i-Pr)(t-BuO)₃).

In various embodiments, a precursor includes at least one alkyl group on each metal atom that can survive the vapor-phase reaction, while other ligands or ions coordinated to the metal atom can be replaced by the counter-reactants. Accordingly, another non-limiting precursor includes an organometallic agent having the formula (VII):

MₐR_{b}L_{c} (VII),

in which M is a metal; R is an optionally substituted alkyl; L is a ligand, ion, or other moiety which is reactive with the counter-reactant; a≥1; b≥1; and c≥1. In particular embodiments, a=1, and b+c=4. In some embodiments, M is Sn, Te, Bi, or Sb. In particular embodiments, each L is independently amino (e.g., —NR¹R², in which each of R¹ and R² can be H or alkyl, such as any described herein), alkoxy (e.g., —OR, in which R is alkyl, such as any described herein), or halo (e.g., F, Cl, Br, or I). Exemplary agents include SnMe₃Cl, SnMe₂Cl₂, SnMeCl₃, SnMe(NMe₂)₃, SnMe₂(NMe₂)₂, SnMe₃(NMe₂), and the like.

In other embodiments, the non-limiting precursor includes an organometallic agent having the formula (VIII):

MₐL_{c} (VIII),

in which M is a metal; L is a ligand, ion, or other moiety which is reactive with the counter-reactant; a≥1; and c≥1. In particular embodiments, c=n−1, and n is 2, 3, or 4. In some embodiments, M is Sn, Te, Bi, or Sb. Counter-reactants preferably have the ability to replace the reactive moieties ligands or ions (e.g., L in formulas herein) so as to link at least two metal atoms via chemical bonding.

In any embodiment herein, R can be an optionally substituted alkyl (e.g., C₁₋₁₀ alkyl). In one embodiment, alkyl is substituted with one or more halo (e.g., halo-substituted C₁₋₁₀ alkyl, including one, two, three, four, or more halo, such as F, Cl, Br, or I). Exemplary R substituents include CₐH₂ₙ₊₁, preferably wherein n≥3; and CₙFₓH_{(2n+1-X)}, wherein 2n+1≤x≤1. In various embodiments, R has at least one beta-hydrogen, beta-halogen, or beta-fluorine. For example, R may be selected from the group consisting of i-propyl, n-propyl, t-butyl, i-butyl, n-butyl, sec-butyl, n-pentyl, i-pentyl, t-pentyl, sec-pentyl, and mixtures thereof.

In any embodiment herein, L may be any moiety readily displaced by a counter-reactant to generate an M-OH moiety, such as a moiety selected from the group consisting of an amino (e.g., —NR¹R², in which each of R¹ and R² can be H or alkyl, such as any described herein), alkoxy (e.g., —OR, in which R is alkyl, such as any described herein), carboxylates, halo (e.g., F, Cl, Br, or I), and mixtures thereof.

Counter-reactants preferably have the ability to replace the reactive moieties, ligands, or ions (e.g., L in formulas herein) so as to link at least two metal atoms via chemical bonding. Exemplary counter-reactants include oxygen-containing counter-reactants, such as oxygen (O₂), ozone (O₃), water, peroxides (e.g., hydrogen peroxide), oxygen plasma, water plasma, alcohols, dihydroxy alcohols, polyhydroxy alcohols, fluorinated dihydroxy alcohol, fluorinated polyhydroxy alcohols, fluorinated glycols, formic acid, and other sources of hydroxyl moieties, as well as combinations thereof. In various embodiments, a counter-reactant reacts with the precursor by forming oxygen bridges between neighboring metal atoms. Other potential counter-reactants include hydrogen sulfide and hydrogen disulfide, which can crosslink metal atoms via sulfur bridges and bis(trimethylsilyl)tellurium, which can crosslink metal atoms via tellurium bridges. In addition, hydrogen iodide may be utilized to incorporate iodine into the film.

Yet other non-limiting counter-reactants include a chalcogenide precursor having the formula ZR₂, wherein: Z is sulfur, selenium, or tellurium; and each R is, independently, H, optionally substituted alkyl (e.g., methyl, ethyl, n-propyl, isopropyl, n-butyl, t-butyl, etc.), optionally substituted alkenyl, optionally substituted aryl, optionally substituted amino, optionally substituted alkoxy, or optionally substituted trialkylsilyl.

Exemplary organometallic agents include SnMeCl₃, (N²,N³-di-t-butyl-butane-2,3-diamido) tin(II) (Sn(tbba)), bis(bis(trimethylsilyl)amido) tin(II), tetrakis(dimethylamino) tin(IV) (Sn(NMe₂)₄), t-butyl tris(dimethylamino) tin (Sn(t-butyl)(NMe₂)₃), i-butyl tris(dimethylamino) tin (Sn(i-Bu)(NMe₂)₃), n-butyl tris(dimethylamino) tin (Sn(n-Bu)(NMe₂)₃), sec-butyl tris(dimethylamino) tin (Sn(s-Bu)(NMe₂)₃), i-propyl(tris)dimethylamino tin (Sn(i-Pr)(NMe₂)₃), n-propyl tris(diethylamino) tin (Sn(n-Pr)(NEt₂)₃), and analogous alkyl(tris)(t-butoxy) tin compounds, such as t-butyl tris(t-butoxy) tin (Sn(t-Bu)(t-BuO)₃). In some embodiments, the organometallic agents are partially fluorinated.

### Lithographic Processes

EUV lithography makes use of EUV resists, which may be polymer-based chemically amplified resists produced by liquid-based spin-on techniques or metal oxide-based resists produced by dry vapor-deposited techniques. Such EUV resists can include any EUV-sensitive film or material described herein. Lithographic methods can include patterning the resist, e.g., by exposure of the EUV resist with EUV radiation to form a photo pattern, followed by developing the pattern by removing a portion of the resist according to the photo pattern to form a mask.

It should also be understood that while the present disclosure relates to lithographic patterning techniques and materials exemplified by EUV lithography, it is also applicable to other next generation lithographic techniques. In addition to EUV, which includes the standard 13.5 nm EUV wavelength currently in use and development, the radiation sources most relevant to such lithography are DUV (deep-UV), which generally refers to use of 248 nm or 193 nm excimer laser sources, X-ray, which formally includes EUV at the lower energy range of the X-ray range, as well as e-beam, which can cover a wide energy range. Such methods include those where a substrate (e.g., optionally having exposed hydroxyl groups) is contacted with a precursor (e.g., any described herein) to form a metal oxide (e.g., a layer including a network of metal oxide bonds, which may include other non-metal and non-oxygen groups) film as the imaging/PR layer on the surface of the substrate. The specific methods may depend on the particular materials and applications used in the semiconductor substrate and ultimate semiconducting device. Thus, the methods described in this application are merely exemplary of the methods and materials that may be used in present technology. In some embodiments, lithography includes use of a radiation source having a wavelength that is between 10 nm and 400 nm.

Directly photopatternable EUV resists may be composed of or contain metals and/or metal oxides. The metals/metal oxides are highly promising in that they can enhance the EUV photon absorption and generate secondary electrons and/or show increased etch selectivity to an underlying film stack and device layers. Additional processes employed during lithography are described in detail below.

### Deposition Processes, Including Dry Deposition

As discussed above, the present disclosure provides methods for films on semiconductor substrates, which may be patterned using EUV or other next generation lithographic techniques. Methods include those where polymerized organometallic materials are produced in a vapor and deposited on a substrate. In some embodiments, dry deposition can employ any useful precursor (e.g., metal halides, capping agents, or organometallic agents described herein). In other embodiments, a spin-on formulation may be used. Deposition processes can include applying a EUV-sensitive material as a resist film or an EUV-sensitive film.

Such EUV-sensitive films comprise materials which, upon exposure to EUV, undergo changes, such as the loss of bulky pendant ligands bonded to metal atoms. If the unexposed region includes a dense M-O-M rich material, then EUV induced cleavage can provide intermediates that are more readily removed by positive tone developers.

Through EUV patterning, areas of the film are created that have altered physical or chemical properties relative to unexposed areas. These properties may be exploited in subsequent processing, such as to dissolve either unexposed or exposed areas or to selectively deposit materials on either the exposed or unexposed areas. In some embodiments, the unexposed film has a hydrophobic surface, and the exposed film has a hydrophilic surface (it being recognized that the hydrophilic properties of exposed and unexposed areas are relative to one another) under the conditions at which such subsequent processing is performed. For example, the removal of material may be performed by leveraging differences in chemical composition, density, and cross-linking of the film. Removal may be by wet processing, as further described herein.

The thickness of the EUV-patternable film formed on the surface of the substrate may vary according to the surface characteristics, materials used, and processing conditions. In various embodiments, the film thickness may range from about 0.5 nm to about 100 nm. Preferably, the film has a sufficient thickness to absorb most of the EUV light under the conditions of EUV patterning. For example, the overall absorption of the resist film may be 30% or less (e.g., 10% or less, or 5% or less), so that the resist material at the bottom of the resist film is sufficiently exposed. In some embodiments, the film thickness is from 10 nm to 20 nm. Without limiting the mechanism, function, or utility of the present disclosure, it is believed that, unlike wet, spin-coating processes of the art, the processes of the present disclosure have fewer restrictions on the surface adhesion properties of the substrate, and therefore can be applied to a wide variety of substrates. Moreover, as discussed above, the deposited films may closely conform to surface features, providing advantages in forming masks over substrates, such as substrates having underlying features, without “filling in” or otherwise planarizing such features.

The film may be composed of a metal oxide layer deposited in any useful manner. Such a metal oxide layer can be deposited or applied by using any EUV-sensitive material described herein, such as a precursor (e.g., metal-containing precursor, a metal halide, a capping agent, or an organometallic agent) in combination with a counter-reactant. In exemplary processes, a polymerized organometallic material is formed in vapor phase or in situ on the surface of the substrate in order to provide the metal oxide layer. The metal oxide layer may be employed as a film, an adhesion layer, or a capping layer.

Optionally, the metal oxide layer can include a hydroxyl-terminated metal oxide layer, which can be deposited by employing a capping agent (e.g., any described herein) with an oxygen-containing counter-reactant. Such a hydroxyl-terminated metal oxide layer can be employed, e.g., as an adhesion layer between two other layers, such as between the substrate and the film and/or between the photoresist layer and the underlayer.

Exemplary deposition techniques (e.g., for a film) include any described herein, such as ALD (e.g., thermal ALD and plasma-enhanced ALD), spin-coat deposition, PVD including PVD co-sputtering, CVD (e.g., PE-CVD or LP-CVD), sputter deposition, e-beam deposition including e-beam co-evaporation, etc., or a combination thereof, such as ALD with a CVD component, such as a discontinuous, ALD-like process in which precursors and counter-reactants are separated in either time or space.

Further description of precursors and methods for their deposition as EUV photoresist films applicable to this disclosure may be found in International Appl. No. PCT/US19/31618, published as International Pub. No. WO2019/217749, filed May 9, 2019, and titled METHODS FOR MAKING EUV PATTERNABLE HARD MASKS. The thin films may include optional materials in addition to a precursor and a counter-reactant to modify the chemical or physical properties of the film, such as to modify the sensitivity of the film to EUV or enhancing etch resistance. Such optional materials may be introduced, such as by doping during vapor phase formation prior to deposition on the substrate, during deposition on the substrate, and/or after deposition of the film. In some embodiments, a gentle remote H₂ plasma may be introduced so as to replace some Sn-L bonds with Sn—H, for example, which can increase reactivity of the resist under EUV. In other embodiments, CO₂ may be introduced to replace some Sn—O bonds with Sn—CO₃ bonds, which can be more resistant to wet development.

In general, methods can include mixing a vapor stream of a precursor (e.g., a metal-containing precursor, such as an organometallic agent) with an optional vapor stream of a counter-reactant so as to form a polymerized organometallic material, and depositing the organometallic material onto the surface of the semiconductor substrate. In some embodiments, mixing the precursor and optional counter-reactant can form a polymerized organometallic material. As will be understood by one of ordinary skill in the art, the mixing and depositing aspects of the process may be concurrent, in a substantially continuous process.

In an exemplary continuous CVD process, two or more gas streams, in separate inlet paths, of sources of precursor and optional counter-reactant are introduced to the deposition chamber of a CVD apparatus, where they mix and react in the gas phase, to form agglomerated polymeric materials (e.g., via metal-oxygen-metal bond formation) or a film on the substrate. Gas streams may be introduced, for example, using separate injection inlets or a dual-plenum showerhead. The apparatus is configured so that the streams of precursor and optional counter-reactant are mixed in the chamber, allowing the precursor and optional counter-reactant to react to form a polymerized organometallic material or a film (e.g., a metal oxide coating or agglomerated polymeric materials, such as via metal-oxygen-metal bond formation).

For depositing metal oxide, the CVD process is generally conducted at reduced pressures, such as from 0.1 Torr to 10 Torr. In some embodiments, the process is conducted at pressures from 1 Torr to 2 Torr. The temperature of the substrate is preferably below the temperature of the reactant streams. For example, the substrate temperature may be from 0° C. to 250° C., or from ambient temperature (e.g., 23° C.) to 150° C.

For depositing agglomerated polymeric materials, the CVD process is generally conducted at reduced pressures, such as from 10 mTorr to 10 Torr. In some embodiments, the process is conducted at from 0.5 to 2 Torr. The temperature of the substrate is preferably at or below the temperature of the reactant streams. For example, the substrate temperature may be from 0° C. to 250° C., or from ambient temperature (e.g., 23° C.) to 150° C. In various processes, deposition of the polymerized organometallic material on the substrate occurs at rates inversely proportional to surface temperature. Without limiting the mechanism, function or utility of present technology, it is believed that the product from such vapor-phase reaction becomes heavier in molecular weight as metal atoms are crosslinked by counter-reactants, and is then condensed or otherwise deposited onto the substrate. In various embodiments, the steric hindrance of the bulky alkyl groups further prevents the formation of densely packed network and produces low density films having increased porosity.

A potential advantage of using dry deposition methods is ease of tuning the composition of the film as it grows. In a CVD process, this may be accomplished by changing the relative flows of a first precursor and a second precursor during deposition. Deposition may occur between 30° C. and 200° C. at pressures between 0.01 Torr to 100 Torr, but more generally between about 0.1 Torr and 10 Torr.

A film (e.g., a metal oxide coating or agglomerated polymeric materials, such as via metal-oxygen-metal bond formation) may also be deposited by an ALD process. For example, the precursor(s) and optional counter-reactant are introduced at separate times, representing an ALD cycle. The precursors react on the surface, forming up to a monolayer of material at a time for each cycle. This may allow for excellent control over the uniformity of film thickness across the surface. The ALD process is generally conducted at reduced pressures, such as from 0.1 Torr to 10 Torr. In some embodiments, the process is conducted from 1 Torr to 2 Torr. The substrate temperature may be from 0° C. to 250° C., or from ambient temperature (e.g., 23° C.) to 150° C. The process may be a thermal process or, preferably, a plasma-assisted deposition.

Any of the deposition methods herein can be modified to allow for use of two or more different precursors. In one embodiment, the precursors can include the same metal but different ligands. In another embodiment, the precursors can include different metal groups. In one non-limiting instance, alternating flows of various volatile precursors can provide a mixed metal-containing layer, such as use of a metal alkoxide precursor having a first metal (e.g., Sn) with a silyl-based precursor having a different second metal (e.g., Te).

Processes herein can be used to achieve a surface modification. In some iterations, a vapor of the precursor may be passed over the wafer. The wafer may be heated to provide thermal energy for the reaction to proceed. In some iterations, the heating can be between about 50° C. to about 250° C. In some cases, pulses of the precursor may be used, separated by pump and/or purging steps. For instance, a first precursor may be pulsed between pulses of a second precursor pulses resulting in ALD or ALD-like growth. In other cases, both precursors may be flowed at the same time. Examples of elements useful for surface modification include I, F, Sn, Bi, Sb, Te, and oxides or alloys of these compounds.

The processes herein can be used to deposit a thin metal oxide or metal by ALD or CVD. Examples include tin oxide (SnOx), bismuth oxide (BiOx), and Te. Following deposition, the film may be capped with an alkyl substituted precursor of the form MₐR_{b}L_{c}, as described elsewhere herein. A counter-reactant may be used to better remove the ligands, and multiple cycles may be repeated to ensure complete saturation of the substrate surface. The surface can then ready for the EUV-sensitive film to be deposited. One possible method is to produce a thin film of SnOx. Possible chemistries include growth of SnO₂ by cycling tetrakis(dimethylamino)tin and a counter-reactant such as water or O₂ plasma. After the growth, a capping agent could be used. For example, isopropyltris(dimethylamino)tin vapor may be flown over the surface.

Deposition processes can be employed on any useful surface. As referred to herein, the “surface” is a surface onto which a film of the present technology is to be deposited or that is to be exposed to EUV during processing. Such a surface can be present on a substrate (e.g., upon which a film is to be deposited), on a film (e.g., upon which a capping layer can be deposited), or on an underlayer.

Any useful substrate can be employed, including any material construct suitable for lithographic processing, particularly for the production of integrated circuits and other semiconducting devices. In some embodiments, substrates are silicon wafers. Substrates may be silicon wafers upon which features have been created (“underlying topographical features”), having an irregular surface topography.

Such underlying topographical features may include regions in which material has been removed (e.g., by etching) or regions in which materials have been added (e.g., by deposition) during processing prior to conducting a method of this technology. Such prior processing may include methods of this technology or other processing methods in an iterative process by which two or more layers of features are formed on the substrate. Without limiting the mechanism, function, or utility of the present technology, it is believed that, in some embodiments, methods of the present technology offer advantages relative to methods among those known in the art in which photolithographic films are deposited on the surface of substrates using spin casting methods. Such advantages may derive from the conformance of the films of the present technology to underlying features without “filling in” or otherwise planarizing such features, and the ability to deposit films on a wide variety of material surfaces.

In some embodiments, the substrate is a hard mask, which is used in lithographic etching of an underlying semiconductor material. The hard mask may comprise any of a variety of materials, including amorphous carbon (a-C), tin oxide (e.g., SnOx), silicon oxide (e.g., SiO₂), silicon oxynitride (e.g., SiOₓN_{y}), silicon oxycarbide (e.g., SiOₓCy), silicon nitride (e.g., Si₃N₄), titanium oxide (e.g., TiO₂), titanium nitride (e.g., TiN), tungsten (e.g., W), doped carbon (e.g., W-doped C), tungsten oxide (e.g., WOₓ), hafnium oxide (e.g., HfO₂), zirconium oxide (e.g., ZrO₂), and aluminum oxide (e.g., Al₂O₃). For example, the substrate may preferably comprise SnOx, such as SnO₂. In various embodiments, the layer may be from 1 nm to 100 nm thick, or from 2 nm to 10 nm thick.

In some non-limiting embodiments, a substrate comprises an underlayer. An underlayer may be deposited on a hard mask or other layer and is generally underneath an imaging layer (or film), as described herein. An underlayer may be used to improve the sensitivity of a PR, increase EUV absorptivity, and/or increase the patterning performance of the PR. In cases where there are device features present on the substrate to be patterned which create significant topography, another important function of the underlayer can be to overcoat and planarize the existing topography so that the subsequent patterning step may be performed on a flat surface with all areas of the pattern in focus. For such applications, the underlayer (or at least one of multiple underlayers) may be applied using spin-coating techniques. When the PR material being employed possesses a significant inorganic component, for example it exhibits a predominately metal oxide framework, the underlayer may advantageously be a carbon-based film, applied either by spin-coating or by dry vacuum-based deposition processes. The layer may include various ashable hard mask (AHM) films with carbon- and hydrogen-based compositions and may be doped with additional elements, such as tungsten, boron, nitrogen, or fluorine.

In various embodiments, the surface (e.g., of the substrate and/or the film) comprises exposed hydroxyl groups on its surface. In general, the surface may be any surface that comprises, or has been treated to produce, an exposed hydroxyl surface. Such hydroxyl groups may be formed on the surface by surface treatment of a substrate using oxygen plasma, water plasma, or ozone. In other embodiments, the surface of the film can be treated to provide exposed hydroxyl groups, upon which a capping layer can be applied. In various embodiments, the hydroxyl-terminated metal oxide layer has a thickness of from 0.1 nm to 20 nm, or from 0.2 nm to 10 nm, or from 0.5 nm to 5 nm.

### EUV Exposure Processes

EUV exposure of the film can provide EUV exposed areas having activated reactive centers including a metal atom (M), which are produced by EUV-mediated cleavage events. Such reactive centers can include dangling metal bonds, M-H groups, cleaved M-ligand groups, dimerized M-M bonds, or M-O-M bridges.

EUV exposure can have a wavelength in the range of about 10 nm to about 20 nm in a vacuum ambient, such as a wavelength of from 10 nm to 15 nm, e.g., 13.5 nm. In particular, patterning can provide EUV exposed areas and EUV unexposed areas to form a pattern.

The present technology can include patterning using EUV, as well as DUV or e-beam. In such patterning, the radiation is focused on one or more regions of the imaging layer. The exposure is typically performed such that imaging layer film comprises one or more regions that are not exposed to the radiation. The resulting imaging layer may comprise a plurality of exposed and unexposed regions, creating a pattern consistent with the creation of transistor or other features of a semiconductor device, formed by addition or removal of material from the substrate in subsequent processing of the substrate. EUV, DUV and e-beam radiation methods and equipment among useful herein include methods and equipment known in the art.

In some EUV lithography techniques, an organic hard mask (e.g., an ashable hard mask of PECVD amorphous hydrogenated carbon) is patterned using a conventional photoresist process. During photoresist exposure, EUV radiation is absorbed in the resist and in the substrate below, producing highly energetic photoelectrons (e.g., about 100 eV) and in turn a cascade of low-energy secondary electrons (e.g., about 10 eV) that diffuse laterally by several nanometers. These electrons increase the extent of chemical reactions in the resist which increases its EUV dose sensitivity. However, a secondary electron pattern that is random in nature is superimposed on the optical image. This unwanted secondary electron exposure results in loss of resolution, observable line edge roughness (LER) and linewidth variation in the patterned resist. These defects are replicated in the material to be patterned during subsequent pattern transfer etching.

A vacuum-integrated metal hard mask process and related vacuum-integrated hardware that combines film formation (deposition/condensation) and optical lithography with the result of greatly improved EUV lithography (EUVL) performance—e.g. reduced line edge roughness—is disclosed herein.

In various embodiments described herein, a deposition (e.g., condensation) process (e.g., ALD or MOCVD carried out in a PECVD tool, such as the Lam Vector®) can be used to form a thin film of a metal-containing film, such a photosensitive metal salt or metal-containing organic compound (organometallic compound), with a strong absorption in the EUV (e.g., at wavelengths on the order of 10 nm to 20 nm), for example at the wavelength of the EUVL light source (e.g., 13.5 nm=91.8 eV). This film photo-decomposes upon EUV exposure and forms a metal mask that is the pattern transfer layer during subsequent etching (e.g., in a conductor etch tool, such as the Lam 2300® Kiyo®).

Following deposition, the EUV-patternable thin film is patterned by exposure to a beam of EUV light, typically under relatively high vacuum. For EUV exposure, the metal-containing film can then be deposited in a chamber integrated with a lithography platform (e.g., a wafer stepper such as the TWINSCAN NXE: 3300B® platform supplied by ASML of Veldhoven, NL) and transferred under vacuum so as not to react before exposure. Integration with the lithography tool is facilitated by the fact that EUVL also requires a greatly reduced pressure given the strong optical absorption of the incident photons by ambient gases such as H₂O, O₂, etc. In other embodiments, the photosensitive metal film deposition and EUV exposure may be conducted in the same chamber.

### Development Processes, Including Wet Development

EUV exposed or unexposed areas can be removed by any useful development process. In one embodiment, the EUV exposed area can have activated reactive centers, such as dangling metal bonds, M-H groups, or dimerized M-M bonds. In other embodiments, EUV exposed areas are removed by use of wet development.

In particular embodiments, a wet development process is used to remove EUV exposed regions to provide a positive tone photoresist. Exemplary, non-limiting wet development can include use of an aqueous developer, a non-aqueous developer, an alkaline developer (e.g., an aqueous alkaline developer or a non-aqueous alkaline developer), such as those including ammonium, e.g., ammonium hydroxide ([NH₄]⁺[OH]⁻); ammonium-based ionic liquids, e.g., tetramethylammonium hydroxide (TMAH), tetraethylammonium hydroxide (TEAH), tetrapropylammonium hydroxide (TPAH), tetrabutylammonium hydroxide (TBAH), or other quaternary alkylammonium hydroxides; an organoamine, such as mono-, di-, and tri-organoamines (e.g., dimethylamine, diethylamine, ethylenediamine, triethylenetetramine); or an alkanolamine, such as monoethanolamine, diethanolamine, triethanolamine, or diethyleneglycolamine. In other embodiments, the alkaline developer can include nitrogen-containing bases, e.g., compounds having the formula R^{N1}NH₂, R^{N1}R^{N2}NH, R^{N1}R^{N2}R^{N3}N, or R^{N1}R^{N2}R^{N3}R^{N4}N⁺X^{N1-}, where each of R^{N1}, R^{N2}, R^{N3}, and R^{N4} is, independently, an organo substituent (e.g., optionally substituted alkyl, optionally substituted hydroxyalkyl, or any described herein), or two or more organo substituents that can be joined together, and X^{N1-} may comprise OH⁻, F⁻, Cl⁻, Br⁻, I⁻, or other art-known quaternary ammonium cationic species. These bases may also comprise heterocyclyl nitrogen compounds known in the art, some of which are described herein.

Other development methodologies can include use of an acidic developer (e.g., an aqueous acidic developer, non-aqueous acidic developer, or an acid developer in an organic solvent) that includes a halide (e.g., HF, HCl, or HBr), an organic acid (e.g., formic acid, acetic acid, oxalic acid, or citric acid), or an organohalide compound (e.g., such as an organofluorine compound, including trifluoroacetic acid; an organochlorine compound; an organobromine compound, or an organoiodine compound); or use of an organic developer, such as a ketone (e.g., 2-heptanone, cyclohexanone, or acetone), an ester (e.g., γ-butyrolactone or ethyl 3-ethoxypropionate (EEP)), an alcohol (e.g., isopropyl alcohol (IPA)), or an ether, such as a glycol ether (e.g., propylene glycol methyl ether (PGME) or propylene glycol methyl ether acetate (PGMEA)), as well as combinations thereof.

Yet other development methodologies can include use of a deprotecting solvent. Non-limiting deprotecting solvents include an organic acid (e.g., any herein, such as oxalic acid) or include choline ([N(CH₃)₃CH₂CH₂OH]⁺), such as choline hydroxide ([N(CH₃)₃CH₂CH₂OH]+[OH]⁻).

The developer can be used in any useful concentration. In one embodiment, the developer solution includes about 0.5 wt. % to about 30 wt. % of the developer(s) in a solvent (e.g., an aqueous solvent, a non-aqueous solvent, an organic solvent, or a combination thereof), including concentrations from about 1 wt. % to about 20 wt. % and 1.1 wt. % to 10 wt. %.

The developer can be used with one or more additives, such as oxidizers, surfactants, salts, and chelating agents. Additives can be optionally present in an amount of less than 10 wt. % or less than 5 wt. % in a developing solution. Non-limiting oxidizers include a peroxide or a peracid, such as hydrogen peroxide, benzoyl peroxide, urea peroxide, or mixtures thereof. Non-limiting surfactants include anionic, cationic, and non-ionic surfactants, such as an alkylphenol ethoxylate (e.g., Triton™ X-100 (polyethylene glycol tert-octylphenyl ether), an octyl phenol ethoxylate, or a nonyl phenol ethoxylate), an alcohol ethoxylate (e.g., BRIJ® 56 (C₁₆H₃₃(OCH₂CH₂)₁₀OH), BRIJ® 58 (C₁₆H₃₃(OCH₂CH₂)₂₀OH), or a fatty alcohol ethoxylate), a fatty acid ethoxylate, a poloxamer, a fatty acid ester of glycerol, an acetylenic diol, an amine ethoxylate, a glucoside, a glucamide, a polyethylene glycol, or poly(ethylene glycol-co-propylene glycol), an ammonium perfluoroalkyl (e.g., ammonium perfluoroalkyl sulfonate or carboxylate), and combinations thereof.

Non-limiting salts include cation(s) selected from the group of ammonium, d-block metal cations (hafnium, zirconium, lanthanum, or the like), f-block metal cations (cerium, lutetium or the like), p-block metal cations (aluminum, tin, or the like), alkali metals (lithium, sodium, potassium or the like), and combinations thereof; and anion(s) selected from the group of fluoride, chloride, bromide, iodide, nitrate, sulfate, phosphate, silicate, borate, peroxide, butoxide, formate, oxalate, ethylenediamine-tetraacetic acid (EDTA), tungstate, molybdate, or the like and combinations thereof. Non-limiting chelating agents can include polyamines, alcohol amines, amino acids, carboxylic acids, or combinations thereof.

In particular embodiments, the positive tone developer is an aqueous alkaline developer (e.g., including NH₄OH, TMAH, TEAH, TPAH, or TBAH, which can be with or without H₂O₂); an aqueous acidic developer (e.g., including HCl or HF); an acidic developer in an organic solvent; an organic developer; or a deprotecting solvent (e.g., including oxalic acid, choline, or choline hydroxide). A developer can include one solvent or a solvent combination.

As described herein, dry development processes can be used to further process a film (e.g., after wet development). Non-limiting processes can include use of halides, such as HCl- or HBr-based processes. While this disclosure is not limited to any particular theory or mechanism of operation, the approach is understood to leverage the chemical reactivity of the dry-deposited EUV photoresist films with the clean chemistry (e.g., HCl, HBr, and BCl₃) to form volatile products using vapors or plasma. The dry-deposited EUV photoresist films can be removed with etch rates of up to 1 nm/s. The quick removal of dry-deposited EUV photoresist films by these chemistries is applicable to chamber cleaning, backside clean, bevel clean, and PR developing. Although the films can be removed using vapors at various temperatures (e.g., HCl or HBr at a temperature greater than −10° C., or BCl₃ at a temperature greater than 80° C., for example), a plasma can also be used to further accelerate or enhance the reactivity.

Plasma processes include transformer coupled plasma (TCP), inductively coupled plasma (ICP) or capacitively coupled plasma (CCP), employing equipment and techniques among those known in the art. For example, a process may be conducted at a pressure of >0.5 mTorr (e.g., such as from 1 mTorr to 100 mTorr), at a power level of <1000 W (e.g., <500 W). Temperatures may be from 30° C. to 300° C. (e.g., 30° C. to 120° C.), at flow rate of 100 to 1000 standard cubic centimeters per minute (sccm), e.g., about 500 sccm, for from 1 to 3000 seconds (e.g., 10 seconds to 600 seconds).

Where the halide reactant flows are of hydrogen gas and halide gas, a remote plasma/UV radiation is used to generate radicals from the H₂ and Cl₂ and/or Br₂, and the hydrogen and halide radicals are flowed to the reaction chamber to contact the patterned EUV photoresist on the substrate layer of the wafer. Suitable plasma power may range from 100 W to 500 W, with no bias. It should be understood that while these conditions are suitable for some processing reactors, e.g., a Kiyo etch tool available from Lam Research Corporation, Fremont, Calif., a wider range of process conditions may be used according to the capabilities of the processing reactor.

In thermal development processes, the substrate is exposed to dry development chemistry (e.g., a Lewis Acid) in a vacuum chamber (e.g., oven). Suitable chambers can include a vacuum line, a dry development hydrogen halide chemistry gas (e.g., HBr, HCl) line, and heaters for temperature control. In some embodiments, the chamber interior can be coated with corrosion resistant films, such as organic polymers or inorganic coatings. One such coating is polytetrafluoroethylene ((PTFE), e.g., Teflon™). Such materials can be used in thermal processes of this disclosure without risk of removal by plasma exposure.

The process conditions for the dry development may be reactant flow of 100 sccm to 500 sccm (e.g., 500 sccm HBr or HCl), temperature of −10° C. to 120° C. (e.g., −10° C.), pressure of 1 mTorr to 500 mTorr (e.g., 300 mTorr) with no plasma and for a time of about 10 sec to 1 min, dependent on the photoresist film and their composition and properties.

In various embodiments, methods of the present disclosure combine all dry steps of film deposition, formation by vapor deposition, (EUV) lithographic photopatterning, and dry development. In such processes, a substrate may directly go to a dry development/etch chamber following photopatterning in an EUV scanner. Such processes may avoid material and productivity costs associated with a wet development. A dry process can also provide more tunability and give further CD control and/or scum removal.

In various embodiments, the EUV photoresist, containing some amount of metal, metal oxide and organic components, can be dry developed by a thermal, plasma (e.g., including possibly photoactivated plasma, such as lamp-heated or UV lamp heated), or a mixture of thermal and plasma methods while flowing a dry development gas including a compound of formula RₓZ_{y}, where R═B, Al, Si, C, S, SO with x>0 and Z═Cl, H, Br, F, CH₄ and y>0. The dry development can result in a positive tone, in which the RₓZ_{y} species selectively removes the exposed material, leaving behind the unexposed counterpart as a mask. In some embodiments, the exposed portions of organotin oxide-based photoresist films are removed by dry development in accordance with this disclosure. Positive tone dry development may be achieved by the selective dry development (removal) of EUV exposed regions exposed to flows comprising hydrogen halides or hydrogen and halides, including HCl and/or HBr without striking a plasma, or flows of H₂ and Cl₂ and/or Br₂ with a remote plasma or UV radiation generated from plasma to generate radicals.

### Other Processes

The methods herein can include any other useful processes, as described below.

For the backside and bevel clean process, the vapor and/or the plasma can be limited to a specific region of the wafer to ensure that only the backside and the bevel are removed, without any film degradation on the frontside of the wafer. The dry-deposited EUV photoresist films being removed are generally composed of Sn, O and C, but the same clean approaches can be extended to films of other metal oxide resists and materials. In addition, this approach can also be used for film strip and PR rework.

Suitable process conditions for a dry bevel edge and backside clean may be a reactant flow of 100 sccm to 500 sccm (e.g., 500 sccm HCl, HBr, or H₂ and Cl₂ or Br₂, BCl₃ or H₂), temperature of −10° C. to 120° C. (e.g., 20° C.), pressure of 20 mTorr to 500 mTorr (e.g., 300 mTorr), plasma power of 0 to 500 W at high frequency (e.g., 13.56 MHz), and for a time of about 10 sec to 20 sec, dependent on the photoresist film and composition and properties. It should be understood that while these conditions are suitable for some processing reactors, e.g., a Kiyo etch tool available from Lam Research Corporation, Fremont, Calif., a wider range of process conditions may be used according to the capabilities of the processing reactor.

Photolithography processes typically involve one or more bake steps, to facilitate the chemical reactions required to produce chemical contrast between exposed and unexposed areas of the photoresist. For high volume manufacturing (HVM), such bake steps are typically performed on tracks where the wafers are baked on a hot-plate at a pre-set temperature under ambient air or in some cases N₂ flow. More careful control of the bake ambient as well as introduction of additional reactive gas component in the ambient during these bake steps can help further reduce the dose requirement and/or improve pattern fidelity.

According to various aspects of this disclosure, one or more post-treatments to metal and/or metal oxide-based photoresists after deposition (e.g., post-application bake (PAB) or another post-application treatment) and/or exposure (e.g., post-exposure bake (PEB), which can be omitted; or another post-exposure treatment) and/or development (e.g., post-development bake (PDB) or another post-development treatment) are capable of increasing material property differences between exposed and unexposed photoresist and therefore decreasing dose to size (DtS), improving PR profile, and improving line edge and width roughness (LER/LWR) after subsequent dry development. Such processing can involve a thermal process with the control of temperature, gas ambient, and moisture, resulting in improved dry development performance in processing to follow. In some instances, a remote plasma might be used.

In the case of post-application processing (e.g., PAB), a thermal process with control of temperature (e.g., with heating or cooling), gas ambient (e.g., air, H₂O, CO₂, CO, O₂, O₃, CH₄, CH₃OH, N₂, H₂, NH₃, N₂O, NO, Ar, He, or their mixtures) or under vacuum, and moisture can be used after deposition and before exposure to change the composition of unexposed metal and/or metal oxide photoresist. The change can increase the EUV sensitivity of the material and thus lower dose to size and edge roughness can be achieved after exposure and dry development.

In the case of post-exposure processing (e.g., PEB), a thermal process with the control of temperature, gas atmosphere (e.g., air, H₂O, CO₂, CO, O₂, O₃, CH₄, CH₃OH, N₂, H₂, NH₃, N₂O, NO, Ar, He, or their mixtures) or under vacuum, and moisture can be used to change the composition of both unexposed and exposed photoresist. The change can increase the composition/material properties difference between the unexposed and exposed photoresist and the etch rate difference of dry development etch gas between the unexposed and exposed photoresist. A higher etch selectivity can thereby be achieved. Due to the improved selectivity, a squarer PR profile can be obtained with improved surface roughness, and/or less photoresist residual/scum. In particular embodiments, PEB can be performed in air and in the optional presence of moisture and CO₂. In other embodiments, PEB can be omitted.

In the case of post-development processing (e.g., post-development bake or PDB), a thermal process with the control of temperature, gas atmosphere (e.g., air, H₂O, CO₂, CO, O₂, O₃, CH₄, CH₃OH, N₂, H₂, NH₃, N₂O, NO, Ar, He, or their mixtures) or under vacuum (e.g., with UV), and moisture can be used to change the composition of the unexposed photoresist. In particular embodiments, the condition also includes use of plasma (e.g., including O₂, O₃, Ar, He, or their mixtures). The change can increase the hardness of material, which can be beneficial if the film will be used as a resist mask when etching the underlying substrate.

In these cases, in alternative implementations, the thermal process could be replaced by a remote plasma process to increase reactive species to lower the energy barrier for the reaction and increase productivity. Remote plasma can generate more reactive radicals and therefore lower the reaction temperature/time for the treatment, leading to increased productivity.

Accordingly, one or multiple processes may be applied to modify the photoresist itself to increase wet or dry development selectivity. This thermal or radical modification can increase the contrast between unexposed and exposed material and thus increase the selectivity of the subsequent development step. The resulting difference between the material properties of unexposed and exposed material can be tuned by adjusting process conditions including temperature, gas flow, moisture, pressure, and/or RF power.

For wet-developed or dry-developed resist films, the treatment temperature in a PAB, PEB, or PDB can be varied to tune and optimize the treatment process, for example from about 90° C. to 250° C. for PAB and about 170° C. to 250° C. or more for PEB and/or PDB. In particular embodiments, PEB is omitted.

In particular embodiments, the PAB, PEB, and/or PDB treatments may be conducted with gas ambient flow in the range of 100 sccm to 10000 sccm, moisture content in the amount of a few percent up to 100% (e.g., 20%-50%), at a pressure between atmospheric and vacuum, and for a duration of about 30 s to 15 min, for example about 1 to 2 min. In particular embodiments, PEB is omitted.

Depending on the selectivity requirements/constraints of the semiconductor processing operation, a thermal treatment such as described herein can be used to lower the EUV dose needed. Or, if higher selectivity is required and higher dose can be tolerated, much higher selectivity, up to 100 times exposed vs. unexposed, can be obtained.

Yet other steps can include in situ metrology, in which physical and structural characteristics (e.g., critical dimension, film thickness, etc.) can be assessed during the photolithography process. Modules to implement in situ metrology include, e.g., scatterometry, ellipsometry, downstream mass spectroscopy, and/or plasma enhanced downstream optical emission spectroscopy modules.

### Apparatuses

The present disclosure also includes any apparatus configured to perform any methods described herein. In one embodiment, the apparatus for depositing a film includes a deposition module comprising a chamber for depositing one or more precursor(s) to provide a film; a patterning module comprising an EUV photolithography tool with a source of sub-30 nm wavelength radiation; and a development module comprising a chamber for developing a film. Post-application treatment can be provided within the deposition module, in another process chamber, or in a separate post-application module. Such post-application modules can include a chamber for optionally removing ambient air and delivering an inert gas or CO₂, as well as configured to be connected to a development module without exposing the film to ambient air, oxygen gas, or another oxidizing gas.

The apparatus can further include a controller having instructions for such modules. In one embodiment, the controller includes one or more memory devices, one or more processors, and system control software coded with instructions for conducting deposition of the film. Such includes can include for, in the deposition module, depositing one or more precursor(s) to provide a film and optionally conducting a PAB or a post-application treatment of the film; in the patterning module, patterning the film with sub-30 nm resolution directly by EUV exposure, thereby forming a pattern within the film; and in the development module, developing the film. In particular embodiments, the development module provides for removal of the EUV exposed or EUV unexposed area(s), thereby providing a pattern within the film. In another embodiment, the apparatus further includes a post-application module, which can provide a process chamber for conducting a post-application bake (PAB) or a post-application treatment of the film.

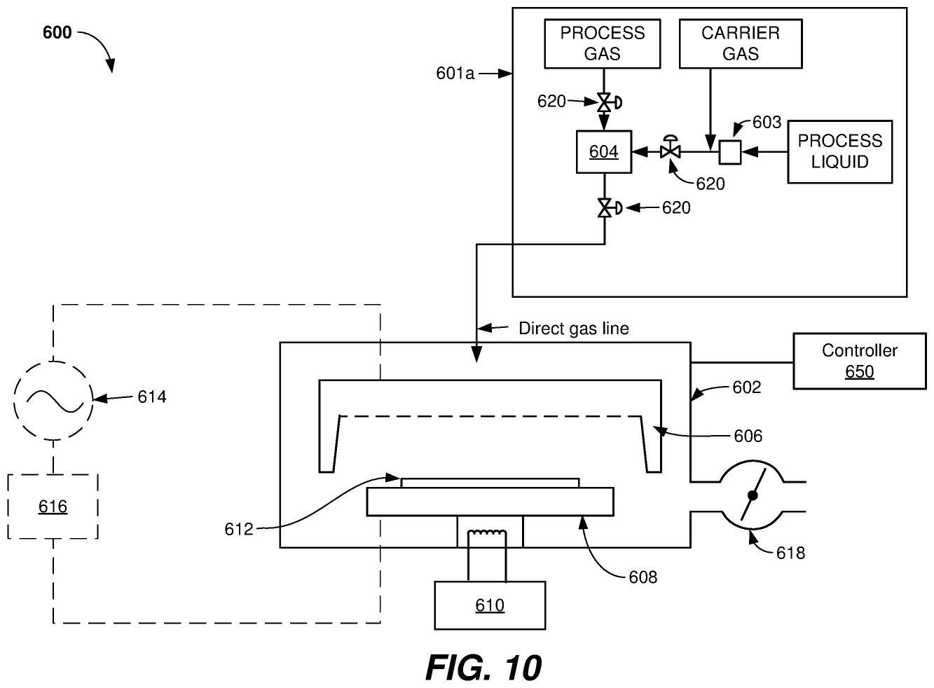

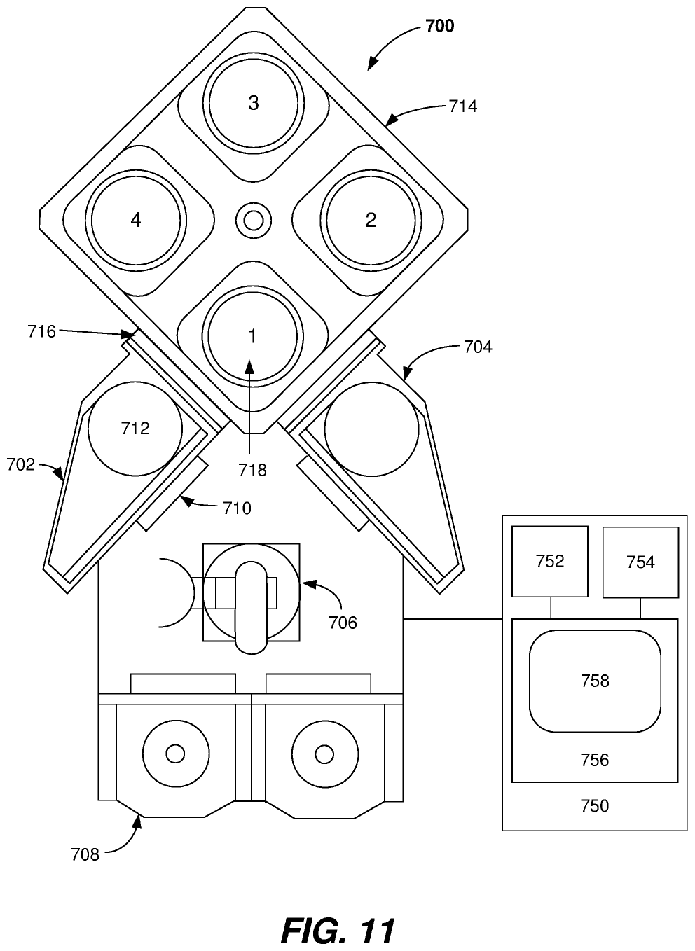

FIG. 10 depicts a schematic illustration of an embodiment of process station 600 having a process chamber body 602 for maintaining a low-pressure environment that is suitable for implementation of described dry deposition and development embodiments as described herein. A plurality of process stations 600 may be included in a common low pressure process tool environment. For example, FIG. 11 depicts an embodiment of a multi-station processing tool 700, such as a VECTOR® processing tool available from Lam Research Corporation, Fremont, Calif. In some embodiments, one or more hardware parameters of the process station 600 including those discussed in detail below may be adjusted programmatically by one or more computer controllers 650.

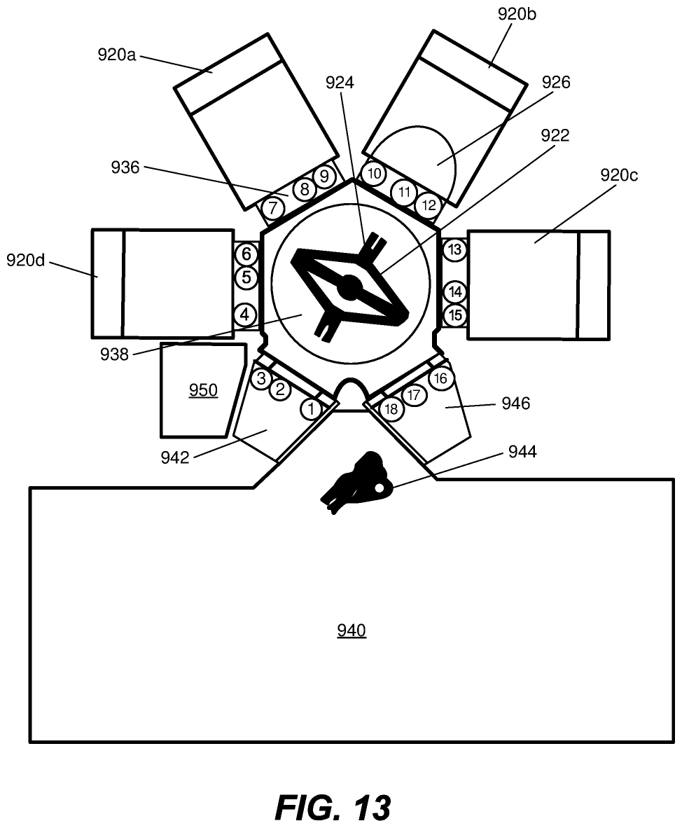

A process station may be configured as a module in a cluster tool. FIG. 13 depicts a semiconductor process cluster tool architecture with vacuum-integrated deposition and patterning modules suitable for implementation of the embodiments described herein. Such a cluster process tool architecture can include resist deposition, resist exposure (EUV scanner), resist dry development and etch modules, as described above and further below with reference to FIGS. 10, 12, and 14.

In some embodiments, certain of the processing functions can be performed consecutively in the same module, for example dry development and etch. And embodiments of this disclosure are directed to methods and apparatus for receiving a wafer, including a photopatterned EUV resist thin film layer disposed on a layer or layer stack to be etched, to a dry development/etch chamber following photopatterning in an EUV scanner; dry developing photopatterned EUV resist thin film layer; and then etching the underlying layer using the patterned EUV resist as a mask, as described herein.

Returning to FIG. 10, process station 600 fluidly communicates with reactant delivery system 601a for delivering process gases to a distribution showerhead 606. Reactant delivery system 601a optionally includes a mixing vessel 604 for blending and/or conditioning process gases, for delivery to showerhead 606. One or more mixing vessel inlet valves 620 may control introduction of process gases to mixing vessel 604. Where plasma exposure is used, plasma may also be delivered to the showerhead 606 or may be generated in the process station 600. As noted above, in at least some embodiments, non-plasma thermal exposure is favored.

FIG. 10 includes an optional vaporization point 603 for vaporizing liquid reactant to be supplied to the mixing vessel 604. In some embodiments, a liquid flow controller (LFC) upstream of vaporization point 603 may be provided for controlling a mass flow of liquid for vaporization and delivery to process station 600. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM.

Showerhead 606 distributes process gases toward substrate 612. In the embodiment shown in FIG. 10, the substrate 612 is located beneath showerhead 606 and is shown resting on a pedestal 608. Showerhead 606 may have any suitable shape, and may have any suitable number and arrangement of ports for distributing process gases to substrate 612.

In some embodiments, pedestal 608 may be raised or lowered to expose substrate 612 to a volume between the substrate 612 and the showerhead 606. It will be appreciated that, in some embodiments, pedestal height may be adjusted programmatically by a suitable computer controller 650.

In some embodiments, pedestal 608 may be temperature controlled via heater 610. In some embodiments, the pedestal 608 may be heated to a temperature of greater than 0° C. and up to 300° C. or more, for example 50 to 120° C., such as about 65 to 80° C., during non-plasma thermal exposure of a photopatterned resist to hydrogen halide dry development chemistry, such as HBr, HCl, or BCl₃, as described in disclosed embodiments.

Further, in some embodiments, pressure control for process station 600 may be provided by a butterfly valve 618. As shown in the embodiment of FIG. 10, butterfly valve 618 throttles a vacuum provided by a downstream vacuum pump (not shown). However, in some embodiments, pressure control of process station 600 may also be adjusted by varying a flow rate of one or more gases introduced to the process station 600.

In some embodiments, a position of showerhead 606 may be adjusted relative to pedestal 608 to vary a volume between the substrate 612 and the showerhead 606. Further, it will be appreciated that a vertical position of pedestal 608 and/or showerhead 606 may be varied by any suitable mechanism within the scope of the present disclosure. In some embodiments, pedestal 608 may include a rotational axis for rotating an orientation of substrate 612. It will be appreciated that, in some embodiments, one or more of these example adjustments may be performed programmatically by one or more suitable computer controllers 650.

Where plasma may be used, for example in gentle plasma-based dry development embodiments and/or etch operations conducted in the same chamber, showerhead 606 and pedestal 608 electrically communicate with a radio frequency (RF) power supply 614 and matching network 616 for powering a plasma. In some embodiments, the plasma energy may be controlled by controlling one or more of a process station pressure, a gas concentration, an RF source power, an RF source frequency, and a plasma power pulse timing. For example, RF power supply 614 and matching network 616 may be operated at any suitable power to form a plasma having a desired composition of radical species. Examples of suitable powers are up to about 500 W.

In some embodiments, instructions for a controller 650 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a recipe phase may include instructions for setting a flow rate of a dry development chemistry reactant gas, such as HBr or HCl, and time delay instructions for the recipe phase. In some embodiments, the controller 650 may include any of the features described below with respect to system controller 750 of FIG. 11.

As described above, one or more process stations may be included in a multi-station processing tool. FIG. 11 shows a schematic view of an embodiment of a multi-station processing tool 700 with an inbound load lock 702 and an outbound load lock 704, either or both of which may include a remote plasma source. A robot 706 at atmospheric pressure is configured to move wafers from a cassette loaded through a pod 708 into inbound load lock 702 via an atmospheric port 710. A wafer is placed by the robot 706 on a pedestal 712 in the inbound load lock 702, the atmospheric port 710 is closed, and the load lock is pumped down. Where the inbound load lock 702 includes a remote plasma source, the wafer may be exposed to a remote plasma treatment to treat the silicon nitride surface in the load lock prior to being introduced into a processing chamber 714. Further, the wafer also may be heated in the inbound load lock 702 as well, for example, to remove moisture and adsorbed gases. Next, a chamber transport port 716 to processing chamber 714 is opened, and another robot (not shown) places the wafer into the reactor on a pedestal of a first station shown in the reactor for processing. While the embodiment depicted in FIG. 11 includes load locks, it will be appreciated that, in some embodiments, direct entry of a wafer into a process station may be provided.

The depicted processing chamber 714 includes four process stations, numbered from 1 to 4 in the embodiment shown in FIG. 11. Each station has a heated pedestal (shown at 718 for station 1), and gas line inlets. It will be appreciated that in some embodiments, each process station may have different or multiple purposes. For example, in some embodiments, a process station may be switchable between dry development and etch process modes. Additionally or alternatively, in some embodiments, processing chamber 714 may include one or more matched pairs of dry development and etch process stations. While the depicted processing chamber 714 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 11 depicts an embodiment of a wafer handling system 790 for transferring wafers within processing chamber 714. In some embodiments, wafer handling system 790 may transfer wafers between various process stations and/or between a process station and a load lock. It will be appreciated that any suitable wafer handling system may be employed. Non-limiting examples include wafer carousels and wafer handling robots. FIG. 11 also depicts an embodiment of a system controller 750 employed to control process conditions and hardware states of process tool 700. System controller 750 may include one or more memory devices 756, one or more mass storage devices 754, and one or more processors 752. Processor 752 may include a CPU or computer, analog, and/or digital input/output connections, stepper motor controller boards, etc.

In some embodiments, system controller 750 controls all of the activities of process tool 700. System controller 750 executes system control software 758 stored in mass storage device 754, loaded into memory device 756, and executed on processor 752. Alternatively, the control logic may be hard coded in the controller 750. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 758 may include instructions for controlling the timing, mixture of gases, gas flow rates, chamber and/or station pressure, chamber and/or station temperature, wafer temperature, target power levels, RF power levels, substrate pedestal, chuck and/or susceptor position, and other parameters of a particular process performed by process tool 700. System control software 758 may be configured in any suitable way. For example, various process tool component subroutines or control objects may be written to control operation of the process tool components used to carry out various process tool processes. System control software 758 may be coded in any suitable computer readable programming language.

In some embodiments, system control software 758 may include input/output control (IOC) sequencing instructions for controlling the various parameters described above. Other computer software and/or programs stored on mass storage device 754 and/or memory device 756 associated with system controller 750 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 718 and to control the spacing between the substrate and other parts of process tool 700.

A process gas control program may include code for controlling hydrogen halide gas composition (e.g., HBr or HCl gas as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 750. The user interface may include a display screen, graphical software displays of the apparatus and/or process conditions, and user input devices such as pointing devices, keyboards, touch screens, microphones, etc.

In some embodiments, parameters adjusted by system controller 750 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 750 from various process tool sensors. The signals for controlling the process may be output on the analog and digital output connections of process tool 700. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 750 may provide program instructions for implementing the above-described deposition processes. The program instructions may control a variety of process parameters, such as DC power level, RF bias power level, pressure, temperature, etc. The instructions may control the parameters to operate dry development and/or etch processes according to various embodiments described herein.

The system controller 750 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 750.

In some implementations, the system controller 750 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 750, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 750 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 750 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 750, in some implementations, may be a part of or coupled to a computer that is integrated with, coupled to the system, otherwise networked to the system, or a combination thereof. For example, the system controller 750 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 750 receives instructions in the form of data, which specify parameters for each of the processing steps to be performed during one or more operations. It should be understood that the parameters may be specific to the type of process to be performed and the type of tool that the system controller 750 is configured to interface with or control. Thus, as described above, the system controller 750 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, an EUV lithography chamber (scanner) or module, a dry development chamber or module, and any other semiconductor processing systems that may be associated or used in the fabrication and/or manufacturing of semiconductor wafers.

As noted above, depending on the process step or steps to be performed by the tool, the system controller 750 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Inductively coupled plasma (ICP) reactors which, in certain embodiments, may be suitable for etch operations suitable for implementation of some embodiments, are now described. Although ICP reactors are described herein, in some embodiments, it should be understood that capacitively coupled plasma reactors may also be used.

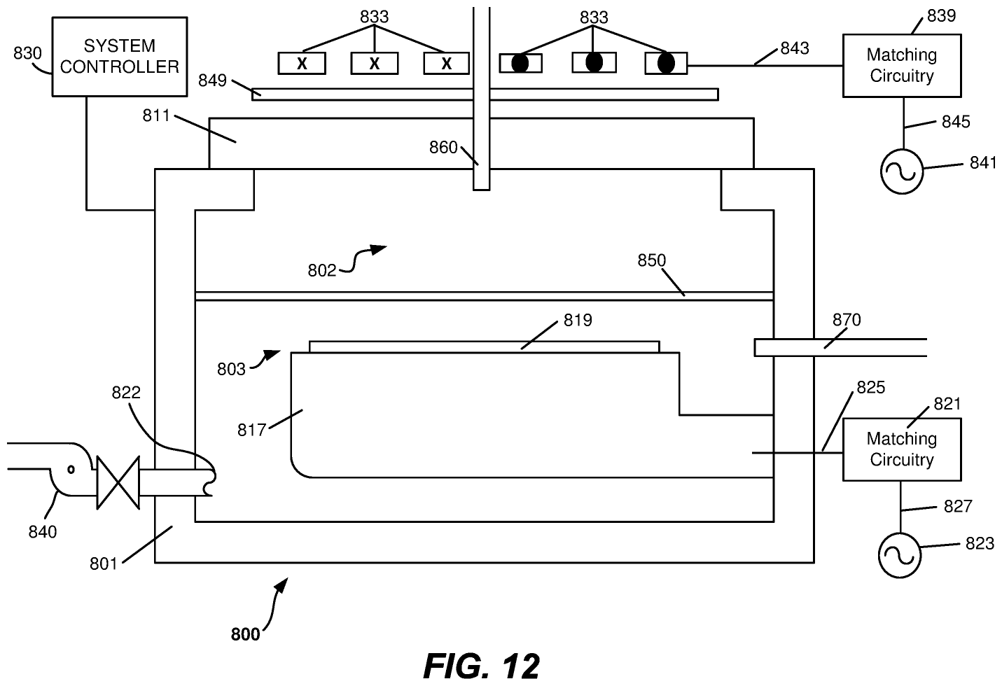

FIG. 12 schematically shows a cross-sectional view of an inductively coupled plasma apparatus 800 appropriate for implementing certain embodiments or aspects of embodiments such as dry development and/or etch, an example of which is a Kiyo® reactor, produced by Lam Research Corp. of Fremont, Calif. In other embodiments, other tools or tool types having the functionality to conduct the dry development and/or etch processes described herein may be used for implementation.

The inductively coupled plasma apparatus 800 includes an overall process chamber 824 structurally defined by chamber walls 801 and a window 811. The chamber walls 801 may be fabricated from stainless steel or aluminum. The window 811 may be fabricated from quartz or other dielectric material. An optional internal plasma grid 850 divides the overall process chamber into an upper sub-chamber 802 and a lower sub chamber 803. In most embodiments, plasma grid 850 may be removed, thereby utilizing a chamber space made of sub chambers 802 and 803. A chuck 817 is positioned within the lower sub-chamber 803 near the bottom inner surface. The chuck 817 is configured to receive and hold a semiconductor wafer 819 upon which the etching and deposition processes are performed. The chuck 817 can be an electrostatic chuck for supporting the wafer 819 when present. In some embodiments, an edge ring (not shown) surrounds chuck 817, and has an upper surface that is approximately planar with a top surface of the wafer 819, when present over chuck 817. The chuck 817 also includes electrostatic electrodes for chucking and dechucking the wafer 819. A filter and DC clamp power supply (not shown) may be provided for this purpose. Other control systems for lifting the wafer 819 off the chuck 817 can also be provided. The chuck 817 can be electrically charged using an RF power supply 823. The RF power supply 823 is connected to matching circuitry 821 through a connection 827. The matching circuitry 821 is connected to the chuck 817 through a connection 825. In this manner, the RF power supply 823 is connected to the chuck 817. In various embodiments, a bias power of the electrostatic chuck may be set at about 50V or may be set at a different bias power depending on the process performed in accordance with disclosed embodiments. For example, the bias power may be between about 20 V and about 100 V, or between about 30 V and about 150 V.

Elements for plasma generation include a coil 833 is positioned above window 811. In some embodiments, a coil is not used in disclosed embodiments. The coil 833 is fabricated from an electrically conductive material and includes at least one complete turn. The example of a coil 833 shown in FIG. 12 includes three turns. The cross sections of coil 833 are shown with symbols, and coils having an “X” extend rotationally into the page, while coils having a “●” extend rotationally out of the page. Elements for plasma generation also include an RF power supply 841 configured to supply RF power to the coil 833. In general, the RF power supply 841 is connected to matching circuitry 839 through a connection 845. The matching circuitry 839 is connected to the coil 833 through a connection 843. In this manner, the RF power supply 841 is connected to the coil 833. An optional Faraday shield 849a is positioned between the coil 833 and the window 811. The Faraday shield 849a may be maintained in a spaced apart relationship relative to the coil 833. In some embodiments, the Faraday shield 849a is disposed immediately above the window 811. In some embodiments, the Faraday shield 849b is between the window 811 and the chuck 817. In some embodiments, the Faraday shield 849b is not maintained in a spaced apart relationship relative to the coil 833. For example, the Faraday shield 849b may be directly below the window 811 without a gap. The coil 833, the Faraday shield 849a, and the window 811 are each configured to be substantially parallel to one another. The Faraday shield 849a may prevent metal or other species from depositing on the window 811 of the process chamber 824.

Process gases may be flowed into the process chamber through one or more main gas flow inlets 860 positioned in the upper sub-chamber 802 and/or through one or more side gas flow inlets 870. Likewise, though not explicitly shown, similar gas flow inlets may be used to supply process gases to a capacitively coupled plasma processing chamber. A vacuum pump, e.g., a one or two stage mechanical dry pump and/or turbomolecular pump 840, may be used to draw process gases out of the process chamber 824 and to maintain a pressure within the process chamber 824. For example, the vacuum pump may be used to evacuate the lower sub-chamber 803 during a purge operation of ALD. A valve-controlled conduit may be used to fluidically connect the vacuum pump to the process chamber 824 so as to selectively control application of the vacuum environment provided by the vacuum pump. This may be done employing a closed loop-controlled flow restriction device, such as a throttle valve (not shown) or a pendulum valve (not shown), during operational plasma processing. Likewise, a vacuum pump and valve controlled fluidic connection to the capacitively coupled plasma processing chamber may also be employed.

During operation of the apparatus 800, one or more process gases may be supplied through the gas flow inlets 860 and/or 870. In certain embodiments, process gas may be supplied only through the main gas flow inlet 860, or only through the side gas flow inlet 870. In some cases, the gas flow inlets shown in the figure may be replaced by more complex gas flow inlets, one or more showerheads, for example. The Faraday shield 849a and/or optional grid 850 may include internal channels and holes that allow delivery of process gases to the process chamber 824. Either or both of Faraday shield 849a and optional grid 850 may serve as a showerhead for delivery of process gases. In some embodiments, a liquid vaporization and delivery system may be situated upstream of the process chamber 824, such that once a liquid reactant or precursor is vaporized, the vaporized reactant or precursor is introduced into the process chamber 824 via a gas flow inlet 860 and/or 870.

Radio frequency power is supplied from the RF power supply 841 to the coil 833 to cause an RF current to flow through the coil 833. The RF current flowing through the coil 833 generates an electromagnetic field about the coil 833. The electromagnetic field generates an inductive current within the upper sub-chamber 802. The physical and chemical interactions of various generated ions and radicals with the wafer 819 etch features of and selectively deposit layers on the wafer 819.

If the plasma grid 850 is used such that there is both an upper sub-chamber 802 and a lower sub-chamber 803, the inductive current acts on the gas present in the upper sub-chamber 802 to generate an electron-ion plasma in the upper sub-chamber 802. The optional internal plasma grid 850 limits the amount of hot electrons in the lower sub-chamber 803. In some embodiments, the apparatus 800 is designed and operated such that the plasma present in the lower sub-chamber 803 is an ion-ion plasma.

Both the upper electron-ion plasma and the lower ion-ion plasma may contain positive and negative ions, though the ion-ion plasma will have a greater ratio of negative ions to positive ions. Volatile etching and/or deposition byproducts may be removed from the lower sub-chamber 803 through port 822. The chuck 817 disclosed herein may operate at elevated temperatures ranging between about 10° C. and about 250° C. The temperature will depend on the process operation and specific recipe.

Apparatus 800 may be coupled to facilities (not shown) when installed in a clean room or a fabrication facility. Facilities include plumbing that provide processing gases, vacuum, temperature control, and environmental particle control. These facilities are coupled to apparatus 800, when installed in the target fabrication facility. Additionally, apparatus 800 may be coupled to a transfer chamber that allows robotics to transfer semiconductor wafers into and out of apparatus 800 using typical automation.

In some embodiments, a system controller 830 (which may include one or more physical or logical controllers) controls some or all of the operations of a process chamber 824. The system controller 830 may include one or more memory devices and one or more processors. In some embodiments, the apparatus 800 includes a switching system for controlling flow rates and durations when disclosed embodiments are performed. In some embodiments, the apparatus 800 may have a switching time of up to about 500 ms, or up to about 750 ms. Switching time may depend on the flow chemistry, recipe chosen, reactor architecture, and other factors.

In some implementations, the system controller 830 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be integrated into the system controller 830, which may control various components or subparts of the system or systems. The system controller, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 830 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication or removal of one or more layers, materials, metals, oxides, silicon, silicon dioxide, surfaces, circuits, and/or dies of a wafer.

The system controller 830, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 830 receives instructions in the form of data, which specify parameters for each of the processing steps to be performed during one or more operations. It should be understood that the parameters may be specific to the type of process to be performed and the type of tool that the controller is configured to interface with or control. Thus, as described above, the system controller 830 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an ALE chamber or module, an ion implantation chamber or module, a track chamber or module, an EUV lithography chamber (scanner) or module, a dry development chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

EUVL patterning may be conducted using any suitable tool, often referred to as a scanner, for example the TWINSCAN NXE: 3300B® platform supplied by ASML of Veldhoven, NL). Processing for dry deposition, PAB, EUV exposure, and wet development may be conducted in separate process chambers, and/or process chambers may be configured as a module in a cluster tool architecture with vacuum-integrated deposition and patterning modules suitable for implementation of the embodiments described herein. In some embodiments, certain of the processing functions can be performed consecutively in the same chamber or module, for example dry deposition and PAB.

The EUVL patterning tool may be a standalone device from which the substrate is moved into and out of for deposition and etching as described herein. Or, as described below, the EUVL patterning tool may be a module on a larger multi-component tool. FIG. 13 depicts a semiconductor process cluster tool architecture with vacuum-integrated deposition, EUV patterning and dry development/etch modules that interface with a vacuum transfer module, suitable for implementation of the processes described herein. While the processes may be conducted without such vacuum integrated apparatus, such apparatus may be advantageous in some implementations.

FIG. 13 depicts a semiconductor process cluster tool architecture with vacuum-integrated deposition and patterning modules that interface with a vacuum transfer module, suitable for implementation of processes described herein. The arrangement of transfer modules to “transfer” wafers among multiple storage facilities and processing modules may be referred to as a “cluster tool architecture” system. Deposition and patterning modules are vacuum-integrated, in accordance with the requirements of a particular process. Other modules, such as for etch, may also be included on the cluster.

A vacuum transport module (VTM) 938 interfaces with four processing modules 920a-920d, which may be individually optimized to perform various fabrication processes. By way of example, processing modules 920a-920d may be implemented to perform deposition, evaporation, ELD, dry development, etch, strip, and/or other semiconductor processes. For example, module 920a may be an ALD reactor that may be operated to perform in a non-plasma, thermal atomic layer depositions as described herein, such as Vector tool, available from Lam Research Corporation, Fremont, Calif. And module 920b may be a PECVD tool, such as the Lam Vector®. It should be understood that the figure is not necessarily drawn to scale.

Airlocks 942 and 946, also known as a loadlocks or transfer modules, interface with the VTM 938 and a patterning module 940. For example, as noted above, a suitable patterning module may be the TWINSCAN NXE: 3300B® platform supplied by ASML of Veldhoven, NL). This tool architecture allows for work pieces, such as semiconductor substrates or wafers, to be transferred under vacuum so as not to react before exposure. Integration of the deposition modules with the lithography tool is facilitated by the fact that EUVL also requires a greatly reduced pressure given the strong optical absorption of the incident photons by ambient gases such as H₂O, O₂, etc.

As noted above, this integrated architecture is just one possible embodiment of a tool for implementation of the described processes. The processes may also be implemented with a more conventional stand-alone EUVL scanner and a deposition reactor, such as a Lam Vector tool, either stand alone or integrated in a cluster architecture with other tools, such as etch, strip etc. (e.g., Lam Kiyo or Gamma tools), as modules, for example as described with reference to FIG. 13 but without the integrated patterning module.

Airlock 942 may be an “outgoing” loadlock, referring to the transfer of a substrate out from the VTM 938 serving a deposition module 920a to the patterning module 940, and airlock 946 may be an “ingoing” loadlock, referring to the transfer of a substrate from the patterning module 940 back in to the VTM 938. The ingoing loadlock 946 may also provide an interface to the exterior of the tool for access and egress of substrates. Each process module has a facet that interfaces the module to VTM 938. For example, deposition process module 920a has facet 936. Inside each facet, sensors, for example, sensors 1-18 as shown, are used to detect the passing of wafer 926 when moved between respective stations. Patterning module 940 and airlocks 942 and 946 may be similarly equipped with additional facets and sensors, not shown.

Main VTM robot 922 transfers wafer 926 between modules, including airlocks 942 and 946. In one embodiment, robot 922 has one arm, and in another embodiment, robot 922 has two arms, where each arm has an end effector 924 to pick wafers such as wafer 926 for transport. Front-end robot 944, in is used to transfer wafers 926 from outgoing airlock 942 into the patterning module 940, from the patterning module 940 into ingoing airlock 946. Front-end robot 944 may also transport wafers 926 between the ingoing loadlock and the exterior of the tool for access and egress of substrates. Because ingoing airlock module 946 has the ability to match the environment between atmospheric and vacuum, the wafer 926 is able to move between the two pressure environments without being damaged.

It should be noted that a EUVL tool typically operates at a higher vacuum than a deposition tool. If this is the case, it is desirable to increase the vacuum environment of the substrate during the transfer between the deposition to the EUVL tool to allow the substrate to degas prior to entry into the patterning tool. Outgoing airlock 942 may provide this function by holding the transferred wafers at a lower pressure, no higher than the pressure in the patterning module 940, for a period of time and exhausting any off-gassing, so that the optics of the patterning tool 940 are not contaminated by off-gassing from the substrate. A suitable pressure for the outgoing, off-gassing airlock is no more than 1E-8 Torr.

In some embodiments, a system controller (which may include one or more physical or logical controllers) controls some or all of the operations of the cluster tool and/or its separate modules. It should be noted that the controller can be local to the cluster architecture, or can be located external to the cluster architecture in the manufacturing floor, or in a remote location and connected to the cluster architecture via a network. The system controller 950 may include one or more memory devices and one or more processors. The processor may include a central processing unit (CPU) or computer, analog and/or digital input/output connections, stepper motor controller boards, and other like components. Instructions for implementing appropriate control operations are executed on the processor. These instructions may be stored on the memory devices associated with the controller or they may be provided over a network. In certain embodiments, the system controller executes system control software.

The system control software may include instructions for controlling the timing of application and/or magnitude of any aspect of tool or module operation. System control software may be configured in any suitable way. For example, various process tool component subroutines or control objects may be written to control operations of the process tool components necessary to carry out various process tool processes. System control software may be coded in any suitable compute readable programming language. In some embodiments, system control software includes input/output control (IOC) sequencing instructions for controlling the various parameters described above. For example, each phase of a semiconductor fabrication process may include one or more instructions for execution by the system controller. The instructions for setting process conditions for condensation, deposition, evaporation, patterning and/or etching phase may be included in a corresponding recipe phase, for example.

It should be noted that the computer controlling the wafer movement can be local to the cluster architecture, or can be located external to the cluster architecture in the manufacturing floor, or in a remote location and connected to the cluster architecture via a network. A controller as described above with respect to any of FIGSs. 10, 11, 12, or 14 may be implemented with the tool in FIG. 13.

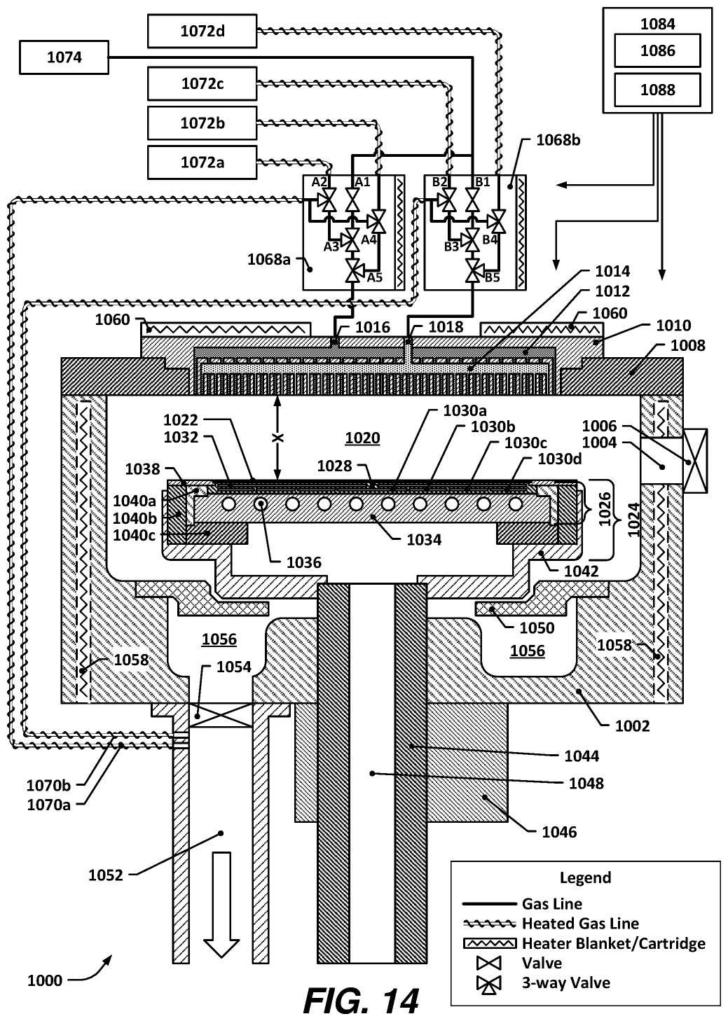

FIG. 14 shows an example of a deposition chamber (e.g., for vapor-based deposition of a film). As can be seen, an apparatus 1000 is depicted that has a processing chamber 1002 that includes a lid 1008. The processing chamber 1002 may include a wafer transfer passage 1004 through one of the walls of the processing chamber 1002 that is sized to allow a substrate 1022 to be passed therethrough and into the interior of the processing chamber 1002, where the substrate 1022 may be placed on a wafer support 1024. The wafer transfer passage 1004 may have a gate valve 1006 or similar door mechanism that may be operated to seal or unseal the wafer transfer passage, thereby allowing the environment within the processing chamber 1002 to be isolated from the environment on the other side of the gate valve 1006. For example, the processing chamber 1002 may be provided substrates 1022 via a wafer handling robot that is located in an adjoining transfer chamber. Such a transfer chamber may, for example, have multiple processing chambers 1002 arranged around its periphery, with each such processing chamber 1002 connected with the transfer chamber via a corresponding gate valve 1006.

The wafer support 1024 may, for example, include an electrostatic chuck (ESC) 1026, which may be used to provide a wafer support surface for supporting the substrate 1022. The ESC 1026 may include, for example, a base plate 1034 that is bonded to a top plate 1028 that is placed atop the base plate 1034. The top plate 1028 may, for example, be made of a ceramic material and may have embedded within it several other components. In the depicted example, the top plate 1028 has two separate electrical systems embedded within it. One such system is an electrostatic clamping electrode system, which may have one or more clamping electrodes 1032 that may be used to generate an electric charge within the substrate 1022 that causes the substrate 1022 to be drawn against the wafer support surface of the top plate 1028. In the implementation of FIG. 14, there are two clamping electrodes 1032 that provide a bi-polar electrostatic clamping system, although some implementations may use only a single clamping electrode 1032 to provide a mono-polar electrostatic clamping system.

The other system is a thermal control system that may be used to control the temperature of the substrate 1022 during processing conditions. In FIG. 14, the thermal control system is a multi-zone thermal control system featuring four annular resistance heater traces 1030a, 1030b, 1030c, and 1030d that are concentric with one another and positioned beneath the clamping electrodes 1032. The center resistance heater traces 1030a may, in some implementations, fill a generally circular area, and each resistance heater trace 1030a/b/c/d may follow a generally serpentine or otherwise meandering path within a corresponding annular region. Each resistance heater trace 1030a/b/c/d may be individually controlled to provide a variety of radial heating profiles in the top plate 1028; such a four-zone heating system may, for example, be controlled to maintain the substrate 1022 so as to have a temperature uniformity of ±0.5° C. in some cases. While the apparatus 1000 of FIG. 14 features a four-zone heating system in the ESC 1026, other implementations may use single-zone or multi-zone heating systems having more or fewer than four zones.

In some implementations, of, for example, temperature control mechanisms discussed above, heat pumps may be used instead of resistance heating traces. For example, in some implementations, the resistance heater traces may be replaced by, or augmented by, Peltier junctions or other, similar devices that may be controlled to “pump” heat from one side thereof to another. Such mechanisms may be used, for example, to draw heat from the top plate 1028 (and thus the substrate 1022) and direct it into the baseplate 1034 and the heat exchange passages 1036, thereby allowing the substrate 1022 to be cooled more rapidly and more effectively, if desired.

The ESC 1026 may also include, for example, a base plate 1034 that may be used to provide structural support to the underside of the top plate 1028 and which may also act as a heat dispersion system. For example, the base plate 1034 may include one or more heat exchange passages 1036 that are arranged in a generally distributed fashion throughout the base plate 1034, e.g., the heat exchange passages 1036 may follow a serpentine, circular switchback, or spiral pattern around the center of the base plate 1034. A heat exchange medium, e.g., water or inert fluorinated liquid, may be circulated through the heat exchange passages 1036 during use. The flow rate and temperature of the heat exchange medium may be externally controlled so as to result in a particular heating or cooling behavior in the base plate 1034.

The ESC 1026 may, for example, be supported by a wafer support housing 1042 that is connected with, and supported by, a wafer support column 1044. The wafer support column 1044 may, for example, have a routing passage 1048 other pass-throughs for routing cabling, fluid flow conduits, and other equipment to the underside of the base plate 1034 and/or the top plate 1028. For example, while not shown in FIG. 14, cabling for providing electrical power to the resistance heater traces 1030a/b/c/d may be routed through the routing passage 1048, as may cabling for providing electrical power to the clamping electrodes 1032. Other cables, e.g., cables for temperature sensors, may also be routed through the routing passage 1048 to locations in the interior of the wafer support 1024. In implementations with a temperature-controllable base plate 1034, conduits for conveying heat exchange medium to and from the base plate 1034 may also be routed through the routing passage 1048. To avoid undue clutter, such cables and conduits are not depicted in FIG. 14, but it is to be understood that they would, nonetheless, be present.

The apparatus 1000 of FIG. 14 also includes a wafer support z-actuator 1046 that may provide movable support to the wafer support column 1044. The wafer support z-actuator 1046 may be actuated to cause the wafer support column 1044, and the wafer support 1024 supported thereby, to move up or down vertically, e.g., by up to several inches, within a reaction space 1020 of the processing chamber 1002. In doing so, a gap distance X between the substrate 1022 and the underside of the showerhead 1010 may be tuned depending on various process conditions.

The wafer support 1024 may also include, in some implementations, one or more edge rings that may be used to control and/or fine-tune various process conditions. In FIG. 14, an upper edge ring 1038 is provided that lies on top of, for example, lower edge rings 1040a and 1040b, which, in turn, are supported by the wafer support housing 1042 and a third lower edge ring 1040c. The upper edge ring 1038 may, for example, be generally subjected to the same processing environment as the substrate 1022, whereas the lower edge rings 1040a/b/c may generally be shielded from the processing environment. Due to the increased exposure of the upper edge ring 1038, the upper edge ring 1038 may have a limited lifespan and may require more frequent replacement or cleaning as compared with the lower edge rings 1040a/b/c.

The apparatus 1000 may also include a system for removing process gases from the processing chamber 1002 during and after processing concludes. For example, the processing chamber 1002 may include an annular plenum 1056 that encircles the wafer support column 1044. The annular plenum 1056 may, in turn, be fluidically connected with a vacuum foreline 1052 that may be connected with a vacuum pump, e.g., such as may be located beneath a subfloor below the apparatus 1000. A regulator valve 1054 may be provided in between the vacuum foreline 1052 and the processing chamber 1002 and actuated to control the flow into the vacuum foreline 1052. In some implementations, a baffle 1050, e.g., an annular plate or other structure that may serve to make the flow into the annular plenum 1056 more evenly distributed about the circumference of the wafer support column 1044, may be provided to reduce the chances of flow non-uniformities developing in reactants flowed across the substrate 1022.

The showerhead 1010, as shown, is a dual-plenum showerhead 1010 and includes a first plenum 1012 that is provided process gas via a first inlet 1016 and a second plenum 1014 that is provided process gas via a second inlet 1018. Generally, two plenums can be employed to maintain separation between the precursor(s) and the counter-reactant(s) prior to release of the precursor and the counter-reactant. The showerhead 1010 may, in some implementations, have more than two plenums. In some instances, a single plenum is used to deliver the precursor(s) into the reaction space 1020 of the processing chamber 1002. Each plenum may have a corresponding set of gas distribution ports that fluidically connect the respective plenum with the reaction space 1020 through the faceplate of the showerhead 1010 (the faceplate being the portion of the showerhead 1010 that is interposed between the lowermost plenum and the reaction space 1020).

The first inlet 1016 and the second inlet 1018 of the showerhead 1010 may be provided processing gases via a gas supply system, which may be configured to provide one or more precursor(s) and/or counter-reactant(s), as discussed herein. The depicted apparatus 1000 is configured to provide multiple precursors and multiple counter-reactants. For example, a first valve manifold 1068a may be configured to provide precursor(s) to the first inlet 1016, while a second valve manifold 1068b may be configured to provide other precursor(s) or other counter-reactants to the second inlet 1018.

A first valve manifold 1068a may be configured to provide one or more precursor(s) to the first inlet 1016, while a second valve manifold 1068b may be configured to provide other precursor(s) or other reactant to the second inlet 1018. In this example, the first valve manifold 1068a, for example, includes multiple valves A1-A5. Valve A2 may, for example, be a three-way valve that has one port fluidically connected with a first vaporizer 1072a, another port fluidically connected with a bypass line 1070a, and a third port fluidically connected with a port on another 3-way valve A3. Similarly, valve A4 may be another three-way valve that has one port fluidically connected with a second vaporizer 1072b, another port fluidically connected with the bypass line 1070a, and a third port fluidically connected with a port on another 3-way valve A5. One of the other ports on valve A5 may be fluidically connected with the first inlet 1016 while the remaining port on valve A5 may be fluidically connected with one of the remaining ports on the valve A3. The remaining port on the valve A3 may, in turn, be fluidically connected with the valve A1 which may be fluidically interposed between the valve A3 and a purge gas source 1074, e.g., nitrogen, argon, or other suitably inert gas (with respect to precursor(s) and/or counter-reactant(s)). In some embodiments, only the first valve manifold is employed.

For the purposes of this disclosure, the term “fluidically connected” is used with respect to volumes, plenums, holes, etc., that may be connected with one another in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet.

The first valve manifold 1068a may, for example, be controllable to cause vapors from one or both of the vaporizers 1072a and 1072b to be flowed either to the processing chamber 1002 or through the first bypass line 1070a and into the vacuum foreline 1052. The first valve manifold 1068a may also be controllable to cause a purge gas to be flowed from the purge gas source 1074 and into the first inlet 1016.

For example, to flow vapor from the first vaporizer 1072a into the reaction space 1020, the valve A2 may be actuated to cause the vapor from the first vaporizer 1072a to first flow into the first bypass line 1070a. This flow may be maintained for a period of time sufficient to allow the flow of the vapor to reach steady state flow conditions. After sufficient time has passed (or after a flow meter, if used, indicates that the flow rate is stable), valves A2, A3, and A5 may be actuated to cause the vapor flow from the first vaporizer 1072a to be directed to the first inlet. Similar operations with valves A4 and A5 may be performed to deliver vapor from the second vaporizer 1072b to the first inlet 1016. In some instances, it may be desirable to purge one of the vapors from the first plenum 1012 by actuating the valves A1, A3, and A5 so as to cause the purge gas from the purge gas source 1074 to be flowed into the first inlet 1016. In some additional implementations, it may be desirable to simultaneously flow vapor from one of the vaporizers 1072a or 1072b in tandem with flowing gas from the purge gas into the first inlet 1016. Such implementations may be used to dilute the concentration of the reactant(s) contained in such vapor(s).

It will be appreciated that the second valve manifold 1068b may be controlled in a similar manner, e.g., by controlling valves B1-B5, to provide vapors from vaporizers 1072c and 1072d to the second inlet 1018 or to the second bypass line 1070b. It will be further appreciated that different manifold arrangements may be utilized as well, including a single unitary manifold that includes valves for controlling flow of the precursor(s), counter-reactant(s), or other reactants to the first inlet 1016 and the second inlet 1018.

As mentioned earlier, some apparatuses 1000 may feature a lesser number of vapor sources, e.g., only two vaporizers 1072, in which case the valve manifold(s) 1068 may be modified to have a lesser number of valves, e.g., only valves A1-A3.

As discussed above, apparatuses such as apparatus 1000, which may be used to provide for dry deposition of films, may be configured to maintain particular temperature profiles within the processing chamber 1002. In particular, such apparatuses 1000 may be configured to maintain the substrate 1022 at a lower temperature, e.g., at least 25° C. to 50° C. lower, than most of the equipment of the apparatus 1002 that comes into direct contact with the precursor(s) and/or counter-reactant(s). Additionally, the temperature of the equipment of the apparatus 1000 that comes into direct contact with the precursor(s) and/or counter-reactant(s) may be kept to an elevated level that is sufficiently high that condensation of the vaporized reactants on the surfaces of such equipment is discouraged. At the same time, the substrate 1022 temperature may be controlled to a level that promotes condensation, or at least deposition, of the reactants on the substrate 1022.

To provide for such temperature control, various heating systems may be included in the apparatus 1000. For example, the processing chamber 1002 may have receptacles for receiving cartridge heaters 1058, e.g., for a processing chamber 1002 that has a generally cylindrical interior volume but a square or rectangular external shape, vertical holes for receiving cartridge heaters 1058 may be bored into the four corners of the chamber 1002 housing. In some implementations, the showerhead 1010 may be covered with heater blankets 1060, which may be used to apply heat across the exposed upper surface of the showerhead 1010 to keep the showerhead temperature elevated. It may also be beneficial to heat various gas lines that are used to conduct the vaporized reactants from the vaporizers 1072 to the showerhead 1010. For example, resistive heater tape may be wound around such gas lines and used to heat them to an elevated temperature. As shown in FIG. 14, all of the gas lines that potentially have precursor(s) and/or counter-reactant(s) flowing through them are shown as being heated, including the bypass lines 1070. The only exceptions are the gas lines from the valve manifolds 1068 to the first inlet 1016 and the second inlet 1018, which may be quite short and may be indirectly heated by the showerhead 1010. Of course, even these gas lines may be actively heated, if desired. In some implementations, heaters may be provided proximate to the gate valve 1006 to provide heat to the gate valve as well.

The various operational systems of the apparatus 1000 may be controlled by a controller 1084, which may include one or more processors 1086 and one or more memory devices 1088 that are operatively connected with each other and that are communicatively connected with various systems and subsystems of the apparatus 1000 so as to provide for control functionality for those systems. For example, the controller 1084 may be configured to control the valves A1-A5 and B1-B5, the various heaters 1058, 1060, the vaporizers 1072, the regulator valve 1054, the gate valve 1006, the wafer support z-actuator, and so forth.

Once the film layer has been deposited on the substrate 1022, the substrate 1022 may, as noted above, be transferred to one or more subsequent processing chambers or tool for additional operations (e.g., any described herein). Further deposition apparatuses are described in International Patent Application No. PCT/US2020/038968, filed Jun. 22, 2020, titled “APPARATUS FOR PHOTORESIST DRY DEPOSITION,” which is herein incorporated by reference in its entirety.

Embodiments of this disclosure are directed to such processing and processing apparatus.

### Definitions

By “acyloxy” or “alkanoyloxy,” as used interchangeably herein, is meant an acyl or alkanoyl group, as defined herein, attached to the parent molecular group through an oxy group. In particular embodiments, the alkanoyloxy is —O—C(O)-Ak, in which Ak is an alkyl group, as defined herein. In some embodiments, an unsubstituted alkanoyloxy is a C₂₋₇ alkanoyloxy group. Exemplary alkanoyloxy groups include acetoxy.

By “alkenyl” is meant an optionally substituted C₂₋₂₄ alkyl group having one or more double bonds. The alkenyl group can be cyclic (e.g., C₃₋₂₄ cycloalkenyl) or acyclic. The alkenyl group can also be substituted or unsubstituted. For example, the alkenyl group can be substituted with one or more substitution groups, as described herein for alkyl. Non-limiting unsubstituted alkenyl groups include allyl and vinyl. In some embodiments, the unsubstituted alkenyl group is a C₂₋₆, C₂₋₈, C₂₋₁₀, C₂₋₁₂, C₂₋₁₆, C₂₋₁₈, C₂₋₂₀, C₂₋₂₄, C₃₋₈, C₃₋₁₀, C₃₋₁₂, C₃₋₁₆, C₃₋₁₈, C₃₋₂₀, or C₃₋₂₄ alkenyl group.

By “alkenylene” is meant a multivalent (e.g., bivalent) form of an alkenyl group, which is an optionally substituted C₂₋₂₄ alkyl group having one or more double bonds. The alkenylene group can be cyclic (e.g., C₃₋₂₄ cycloalkenyl) or acyclic. The alkenylene group can be substituted or unsubstituted. For example, the alkenylene group can be substituted with one or more substitution groups, as described herein for alkyl. Exemplary, non-limiting alkenylene groups include —CH═CH— or —CH═CHCH₂—.

By “alkoxy” is meant —OR, where R is an optionally substituted alkyl group, as described herein. Exemplary alkoxy groups include methoxy, ethoxy, butoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkyl” and the prefix “alk” is meant a branched or unbranched saturated hydrocarbon group of 1 to 24 carbon atoms, such as methyl (Me), ethyl (Et), n-propyl (n-Pr), isopropyl (i-Pr), cyclopropyl, n-butyl (n-Bu), isobutyl (i-Bu), s-butyl (s-Bu), t-butyl (t-Bu), cyclobutyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic (e.g., C₃₋₂₄ cycloalkyl) or acyclic. The alkyl group can be branched or unbranched. The alkyl group can also be substituted or unsubstituted. For example, the alkyl group can include haloalkyl, in which the alkyl group is substituted by one or more halo groups, as described herein. In another example, the alkyl group can be substituted with one, two, three or, in the case of alkyl groups of two carbons or more, four substituents independently selected from the group consisting of: (1) C₁₋₆ alkoxy (e.g., —O-Ak, wherein Ak is optionally substituted C₁₋₆ alkyl); (2) amino (e.g., —NR^{N1}R^{N2}, where each of R^{N1} and R^{N2} is, independently, H or optionally substituted alkyl, or R^{N1} and R^{N2}, taken together with the nitrogen atom to which each are attached, form a heterocyclyl group); (3) aryl; (4) arylalkoxy (e.g., —O-Lk-Ar, wherein Lk is a bivalent form of optionally substituted alkyl and Ar is optionally substituted aryl); (5) aryloyl (e.g., —C(O)—Ar, wherein Ar is optionally substituted aryl); (6) cyano (e.g., —CN); (7) carboxyaldehyde (e.g., —C(O)H); (8) carboxyl (e.g., —CO₂H); (9) C₃₋₈ cycloalkyl (e.g., a monovalent saturated or unsaturated non-aromatic cyclic C₃_₈ hydrocarbon group); (10) halo (e.g., F, Cl, Br, or I); (11) heterocyclyl (e.g., a 5-, 6- or 7-membered ring, unless otherwise specified, containing one, two, three, or four non-carbon heteroatoms, such as nitrogen, oxygen, phosphorous, sulfur, or halo); (12) heterocyclyloxy (e.g., —O-Het, wherein Het is heterocyclyl, as described herein); (13) heterocyclyloyl (e.g., —C(O)—Het, wherein Het is heterocyclyl, as described herein); (14) hydroxyl (e.g., —OH); (15)N-protected amino; (16) nitro (e.g., —NO₂); (17) oxo (e.g., ═O); (18) —CO₂R^{A}, where R^{A} is selected from the group consisting of (a) C₁₋₆ alkyl, (b) C₄₋₁₈ aryl, and (c) (C₄₋₁₈ aryl) C₁₋₆ alkyl (e.g., -Lk-Ar, wherein Lk is a bivalent form of optionally substituted alkyl group and Ar is optionally substituted aryl); (19) —C(O)NR^{B}R^{C}, where each of R^{B} and R^{C} is, independently, selected from the group consisting of (a) hydrogen, (b) C₁₋₆ alkyl, (c) C₄₋₁₈ aryl, and (d) (C₄₋₁₈ aryl) C₁₋₆ alkyl (e.g., -Lk-Ar, wherein Lk is a bivalent form of optionally substituted alkyl group and Ar is optionally substituted aryl); and (20) —NR^{G}R^{H}, where each of R^{G} and R^{H} is, independently, selected from the group consisting of (a) hydrogen, (b) an N-protecting group, (c) C₁₋₆ alkyl, (d) C₂₋₆ alkenyl (e.g., optionally substituted alkyl having one or more double bonds), (e) C₂₋₆ alkynyl (e.g., optionally substituted alkyl having one or more triple bonds), (f) C₄₋₁₈ aryl, (g) (C₄₋₁₈ aryl) C₁₋₆ alkyl (e.g., Lk-Ar, wherein Lk is a bivalent form of optionally substituted alkyl group and Ar is optionally substituted aryl), (h) C₃₋₈ cycloalkyl, and (i) (C₃₋₈ cycloalkyl) C₁₋₆ alkyl (e.g., -Lk-Cy, wherein Lk is a bivalent form of optionally substituted alkyl group and Cy is optionally substituted cycloalkyl, as described herein), wherein in one embodiment no two groups are bound to the nitrogen atom through a carbonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₈, C₁₋₁₀, C₁₋₁₂, C₁₋₁₆, C₁₋₁₈, C₁₋₂₀, C₁₋₂₄, C₂₋₆, C₂₋₈, C₂₋₁₀, C₂₋₁₂, C₂₋₁₆, C₂₋₁₈, C₂₋₂₀, C₂₋₂₄, C₃₋₈, C₃₋₁₀, C₃₋₁₂, C₃₋₁₆, C₃₋₁₈, C₃₋₂₀, or C₃₋₂₄ alkyl group.

By “alkylene” is meant a multivalent (e.g., bivalent) form of an alkyl group, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. The alkylene group can be branched or unbranched. The alkylene group can also be substituted or unsubstituted. For example, the alkylene group can be substituted with one or more substitution groups, as described herein for alkyl.

By “alkynyl” is meant an optionally substituted C₂₋₂₄ alkyl group having one or more triple bonds. The alkynyl group can be cyclic or acyclic and is exemplified by ethynyl, 1-propynyl, and the like. The alkynyl group can also be substituted or unsubstituted. For example, the alkynyl group can be substituted with one or more substitution groups, as described herein for alkyl. In some embodiments, the unsubstituted alkynyl group is a C₂₋₆, C₂₋₈, C₂₋₁₀, C₂₋₁₂, C₂₋₁₆, C₂₋₁₈, C₂₋₂₀, C₂₋₂₄, C₃₋₈, C₃₋₁₀, C₃₋₁₂, C₃₋₁₆, C₃₋₁₈, C₃₋₂₀, or C₃₋₂₄ alkynyl group.

By “alkynylene” is meant a multivalent (e.g., bivalent) form of an alkynyl group, which is an optionally substituted C₂₋₂₄ alkyl group having one or more triple bonds. The alkynylene group can be cyclic or acyclic. The alkynylene group can be substituted or unsubstituted. For example, the alkynylene group can be substituted with one or more substitution groups, as described herein for alkyl. Exemplary, non-limiting alkynylene groups include —C≡C— or —C≡CCH₂—.

By “amino” is meant —NR^{N1}R^{N2}, where each of R^{N1} and R^{N2} is, independently, H, optionally substituted alkyl, or optionally substituted aryl, or R^{N1} and R^{N2}, taken together with the nitrogen atom to which each are attached, form a heterocyclyl group, as defined herein.

By “aryl” is meant a group that contains any carbon-based aromatic group including, but not limited to, phenyl, benzyl, anthracenyl, anthryl, benzocyclobutenyl, benzocyclooctenyl, biphenylyl, chrysenyl, dihydroindenyl, fluoranthenyl, indacenyl, indenyl, naphthyl, phenanthryl, phenoxybenzyl, picenyl, pyrenyl, terphenyl, and the like, including fused benzo-C₄₋₈ cycloalkyl radicals (e.g., as defined herein) such as, for instance, indanyl, tetrahydronaphthyl, fluorenyl, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents, such as any described herein for alkyl.

By “arylene” is meant a multivalent (e.g., bivalent) form of an aryl group, as described herein. Exemplary arylene groups include phenylene, naphthylene, biphenylene, triphenylene, diphenyl ether, acenaphthenylene, anthrylene, or phenanthrylene. In some embodiments, the arylene group is a C₄₋₁₈, C₄₋₁₄, C₄₋₁₂, C₄₋₁₀, C₆₋₁₈, C₆₋₁₄, C₆₋₁₂, or C₆₋₁₀ arylene group. The arylene group can be branched or unbranched. The arylene group can also be substituted or unsubstituted. For example, the arylene group can be substituted with one or more substitution groups, as described herein for alkyl or aryl.

By “(aryl)(alkyl)ene” is meant a bivalent form including an arylene group, as described herein, attached to an alkylene or a heteroalkylene group, as described herein. In some embodiments, the (aryl)(alkyl)ene group is -L-Ar— or -L-Ar-L- or —Ar-L-, in which Ar is an arylene group and each L is, independently, an optionally substituted alkylene group or an optionally substituted heteroalkylene group.

By “carbonyl” is meant a —C(O)— group, which can also be represented as >C═O, or a —CO group.

By “carboxyl” is meant a —CO₂H group.

By “carboxyalkyl” is meant an alkyl group, as defined herein, substituted by one or more carboxyl groups, as defined herein.

By “carboxyaryl” is meant an aryl group, as defined herein, substituted by one or more carboxyl groups, as defined herein.

By “cyclic anhydride” is meant a 3-, 4-, 5-, 6- or 7-membered ring (e.g., a 5-, 6-or 7-membered ring), unless otherwise specified, having a —C(O)—O—C(O)— group within the ring. The term “cyclic anhydride” also includes bicyclic, tricyclic and tetracyclic groups in which any of the above rings is fused to one, two, or three rings independently selected from the group consisting of an aryl ring, a cyclohexane ring, a cyclohexene ring, a cyclopentane ring, a cyclopentene ring, and another monocyclic heterocyclic ring. Exemplary cyclic anhydride groups include a radical formed from succinic anhydride, glutaric anhydride, maleic anhydride, phthalic anhydride, isochroman-1,3-dione, oxepanedione, tetrahydrophthalic anhydride, hexahydrophthalic anhydride, pyromellitic dianhydride, naphthalic anhydride, 1,2-cyclohexanedicarboxylic anhydride, etc., by removing one or more hydrogen. Other exemplary cyclic anhydride groups include dioxotetrahydrofuranyl, dioxodihydroisobenzofuranyl, etc. The cyclic anhydride group can also be substituted or unsubstituted. For example, the cyclic anhydride group can be substituted with one or more groups including those described herein for heterocyclyl.

By “cycloalkenyl” is meant a monovalent unsaturated non-aromatic or aromatic cyclic hydrocarbon group of from three to eight carbons, unless otherwise specified, having one or more double bonds. The cycloalkenyl group can also be substituted or unsubstituted. For example, the cycloalkenyl group can be substituted with one or more groups including those described herein for alkyl.

By “cycloalkyl” is meant a monovalent saturated or unsaturated non-aromatic or aromatic cyclic hydrocarbon group of from three to eight carbons, unless otherwise specified, and is exemplified by cyclopropyl, cyclobutyl, cyclopentyl, cyclopentadienyl, cyclohexyl, cycloheptyl, bicyclo[2.2.1.]heptyl, and the like. The cycloalkyl group can also be substituted or unsubstituted. For example, the cycloalkyl group can be substituted with one or more groups including those described herein for alkyl.

By “halo” is meant F, Cl, Br, or I.

By “haloalkenyl” is meant an alkenyl group, as defined herein, substituted with one or more halo.

By “haloalkyl” is meant an alkyl group, as defined herein, substituted with one or more halo.

By “haloalkynyl” is meant an alkynyl group, as defined herein, substituted with one or more halo.

By “haloaryl” is meant an aryl group, as defined herein, substituted with one or more halo.

By “heteroalkyl” is meant an alkyl group, as defined herein, containing one, two, three, or four non-carbon heteroatoms (e.g., independently selected from the group consisting of nitrogen, oxygen, phosphorous, sulfur, selenium, or halo).

By “heteroalkylene” is meant a bivalent form of an alkylene group, as defined herein, containing one, two, three, or four non-carbon heteroatoms (e.g., independently selected from the group consisting of nitrogen, oxygen, phosphorous, sulfur, selenium, or halo). The heteroalkylene group can be substituted or unsubstituted. For example, the heteroalkylene group can be substituted with one or more substitution groups, as described herein for alkyl.

By “heterocyclyl” is meant a 3-, 4-, 5-, 6- or 7-membered ring (e.g., a 5-, 6- or 7-membered ring), unless otherwise specified, containing one, two, three, or four non-carbon heteroatoms (e.g., independently selected from the group consisting of nitrogen, oxygen, phosphorous, sulfur, selenium, or halo). The 3-membered ring has zero to one double bonds, the 4- and 5-membered ring has zero to two double bonds, and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include acridinyl, adenyl, alloxazinyl, azaadamantanyl, azabenzimidazolyl, azabicyclononyl, azacycloheptyl, azacyclooctyl, azacyclononyl, azahypoxanthinyl, azaindazolyl, azaindolyl, azecinyl, azepanyl, azepinyl, azetidinyl, azetyl, aziridinyl, azirinyl, azocanyl, azocinyl, azonanyl, benzimidazolyl, benzisothiazolyl, benzisoxazolyl, benzodiazepinyl, benzodiazocinyl, benzodihydrofuryl, benzodioxepinyl, benzodioxinyl, benzodioxanyl, benzodioxocinyl, benzodioxolyl, benzodithiepinyl, benzodithiinyl, benzodioxocinyl, benzofuranyl, benzophenazinyl, benzopyranonyl, benzopyranyl, benzopyrenyl, benzopyronyl, benzoquinolinyl, benzoquinolizinyl, benzothiadiazepinyl, benzothiadiazolyl, benzothiazepinyl, benzothiazocinyl, benzothiazolyl, benzothienyl, benzothiophenyl, benzothiazinonyl, benzothiazinyl, benzothiopyranyl, benzothiopyronyl, benzotriazepinyl, benzotriazinonyl, benzotriazinyl, benzotriazolyl, benzoxathiinyl, benzotrioxepinyl, benzoxadiazepinyl, benzoxathiazepinyl, benzoxathiepinyl, benzoxathiocinyl, benzoxazepinyl, benzoxazinyl, benzoxazocinyl, benzoxazolinonyl, benzoxazolinyl, benzoxazolyl, benzylsultamyl benzylsultimyl, bipyrazinyl, bipyridinyl, carbazolyl (e.g., 4H-carbazolyl), carbolinyl (e.g., β-carbolinyl), chromanonyl, chromanyl, chromenyl, cinnolinyl, coumarinyl, cytdinyl, cytosinyl, decahydroisoquinolinyl, decahydroquinolinyl, diazabicyclooctyl, diazetyl, diaziridinethionyl, diaziridinonyl, diaziridinyl, diazirinyl, dibenzisoquinolinyl, dibenzoacridinyl, dibenzocarbazolyl, dibenzofuranyl, dibenzophenazinyl, dibenzopyranonyl, dibenzopyronyl (xanthonyl), dibenzoquinoxalinyl, dibenzothiazepinyl, dibenzothiepinyl, dibenzothiophenyl, dibenzoxepinyl, dihydroazepinyl, dihydroazetyl, dihydrofuranyl, dihydrofuryl, dihydroisoquinolinyl, dihydropyranyl, dihydropyridinyl, dihydroypyridyl, dihydroquinolinyl, dihydrothienyl, dihydroindolyl, dioxanyl, dioxazinyl, dioxindolyl, dioxiranyl, dioxenyl, dioxinyl, dioxobenzofuranyl, dioxolyl, dioxotetrahydrofuranyl, dioxothiomorpholinyl, dithianyl, dithiazolyl, dithienyl, dithiinyl, furanyl, furazanyl, furoyl, furyl, guaninyl, homopiperazinyl, homopiperidinyl, hypoxanthinyl, hydantoinyl, imidazolidinyl, imidazolinyl, imidazolyl, indazolyl (e.g., 1H-indazolyl), indolenyl, indolinyl, indolizinyl, indolyl (e.g., 1H-indolyl or 3H-indolyl), isatinyl, isatyl, isobenzofuranyl, isochromanyl, isochromenyl, isoindazoyl, isoindolinyl, isoindolyl, isopyrazolonyl, isopyrazolyl, isoxazolidiniyl, isoxazolyl, isoquinolinyl, isoquinolinyl, isothiazolidinyl, isothiazolyl, morpholinyl, naphthindazolyl, naphthindolyl, naphthiridinyl, naphthopyranyl, naphthothiazolyl, naphthothioxolyl, naphthotriazolyl, naphthoxindolyl, naphthyridinyl, octahydroisoquinolinyl, oxabicycloheptyl, oxauracil, oxadiazolyl, oxazinyl, oxaziridinyl, oxazolidinyl, oxazolidonyl, oxazolinyl, oxazolonyl, oxazolyl, oxepanyl, oxetanonyl, oxetanyl, oxetyl, oxtenayl, oxindolyl, oxiranyl, oxobenzoisothiazolyl, oxochromenyl, oxoisoquinolinyl, oxoquinolinyl, oxothiolanyl, phenanthridinyl, phenanthrolinyl, phenazinyl, phenothiazinyl, phenothienyl (benzothiofuranyl), phenoxathiinyl, phenoxazinyl, phthalazinyl, phthalazonyl, phthalidyl, phthalimidinyl, piperazinyl, piperidinyl, piperidonyl (e.g., 4-piperidonyl), pteridinyl, purinyl, pyranyl, pyrazinyl, pyrazolidinyl, pyrazolinyl, pyrazolopyrimidinyl, pyrazolyl, pyridazinyl, pyridinyl, pyridopyrazinyl, pyridopyrimidinyl, pyridyl, pyrimidinyl, pyrimidyl, pyronyl, pyrrolidinyl, pyrrolidonyl (e.g., 2-pyrrolidonyl), pyrrolinyl, pyrrolizidinyl, pyrrolyl (e.g., 2H-pyrrolyl), pyrylium, quinazolinyl, quinolinyl, quinolizinyl (e.g., 4H-quinolizinyl), quinoxalinyl, quinuclidinyl, selenazinyl, selenazolyl, selenophenyl, succinimidyl, sulfolanyl, tetrahydrofuranyl, tetrahydrofuryl, tetrahydroisoquinolinyl, tetrahydroisoquinolyl, tetrahydropyridinyl, tetrahydropyridyl (piperidyl), tetrahydropyranyl, tetrahydropyronyl, tetrahydroquinolinyl, tetrahydroquinolyl, tetrahydrothienyl, tetrahydrothiophenyl, tetrazinyl, tetrazolyl, thiadiazinyl (e.g., 6H-1,2,5-thiadiazinyl or 2H,6H-1,5,2-dithiazinyl), thiadiazolyl, thianthrenyl, thianyl, thianaphthenyl, thiazepinyl, thiazinyl, thiazolidinedionyl, thiazolidinyl, thiazolyl, thienyl, thiepanyl, thiepinyl, thietanyl, thietyl, thiiranyl, thiocanyl, thiochromanonyl, thiochromanyl, thiochromenyl, thiodiazinyl, thiodiazolyl, thioindoxyl, thiomorpholinyl, thiophenyl, thiopyranyl, thiopyronyl, thiotriazolyl, thiourazolyl, thioxanyl, thioxolyl, thymidinyl, thyminyl, triazinyl, triazolyl, trithianyl, urazinyl, urazolyl, uretidinyl, uretinyl, uricyl, uridinyl, xanthenyl, xanthinyl, xanthionyl, and the like, as well as modified forms thereof (e.g., including one or more oxo and/or amino) and salts thereof. The heterocyclyl group can be substituted or unsubstituted. For example, the heterocyclyl group can be substituted with one or more substitution groups, as described herein for alkyl.

By “hydrocarbyl” is meant a univalent group formed by removing a hydrogen atom from a hydrocarbon. Non-limiting unsubstituted hydrocarbyl groups include alkyl, alkenyl, alkynyl, and aryl, as defined herein, in which these groups include only carbon and hydrogen atoms. The hydrocarbyl group can be substituted or unsubstituted. For example, the hydrocarbyl group can be substituted with one or more substitution groups, as described herein for alkyl. In other embodiments, any alkyl or aryl group herein can be replaced with a hydrocarbyl group, as defined herein.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like.

By “hydroxyaryl” is meant an aryl group, as defined herein, substituted by one to three hydroxyl groups, with the proviso that no more than one hydroxyl group may be attached to a single carbon atom of the aryl group and is exemplified by hydroxyphenyl, dihydroxyphenyl, and the like.

By “isocyanato” is meant —NCO.

By “oxido” is meant an —O⁻ group.

By “oxo” is meant an ═O group.

By “phosphine” is meant a trivalent or tetravalent phosphorous having hydrocarbyl moieties. In some embodiments, phosphine is a —PR^{P}₃ group, where each R^{P} is, independently, H, optionally substituted alkyl, or optionally substituted aryl. The phosphine group can be substituted or unsubstituted. For example, the phosphine group can be substituted with one or more substitution groups, as described herein for alkyl.

By “selenol” is meant an —SeH group.

By “tellurol” is meant an —TeH group.

By “thioisocyanato” is meant —NCS.

By “thiol” is meant an —SH group.

As used herein, the terms “top,” “bottom,” “upper,” “lower,” “above,” and “below” are used to provide a relative relationship between structures. The use of these terms does not indicate or require that a particular structure must be located at a particular location in the apparatus.

### CONCLUSION

Process and apparatus for positive tone development of dry deposited (e.g., by chemical vapor deposition (CVD)) EUV photopatternable resist films, is disclosed.

It is understood that the examples and embodiments described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein, but may be modified within the scope of the disclosure.

The following sample claims are provided for further illustration of certain embodiments of the disclosure. The disclosure is not necessarily limited to these embodiments.

1. A method comprising:
providing a substrate to receive a pattern;
applying a radiation-sensitive resist film on a surface of the substrate;
conducting a post-application bake (PAB) or a post-application treatment of the radiation-sensitive resist film, thereby providing a hardened resist film;
exposing the hardened resist film to a patterning radiation source, thereby providing an exposed resist film; and
developing the exposed resist film to form the pattern by a positive tone wet development process.

2. The method of claim 1, wherein the radiation-sensitive film comprises an Extreme Ultraviolet (EUV)-sensitive film, and wherein the patterning radiation source is an EUV radiation source.

3. The method of claim 1, wherein said conducting comprises condensing the radiation-sensitive resist film by increasing a content of metal-oxygen-metal bonds and/or decreasing a content of metal-hydroxyl bonds.

4. The method of claim 1, wherein said applying comprises a dry deposition process.

5. The method of claim 4, wherein said applying comprises:
providing one or more precursors comprising a structure having formula (I) or (II) to the surface of the substrate:
MₐR_{b} (I),
wherein:
M is a metal or an atom having a high EUV absorption cross-section;
each R is, independently, H, halo, optionally substituted alkyl, optionally substituted cycloalkyl, optionally substituted cycloalkenyl, optionally substituted alkenyl, optionally substituted alkynyl, optionally substituted alkoxy, optionally substituted alkanoyloxy, optionally substituted aryl, optionally substituted amino, optionally substituted bis(trialkylsilyl)amino, optionally substituted trialkylsilyl, oxo, an anionic ligand, a neutral ligand, or a multidentate ligand;
a≥1; and b≥1; or
MₐR_{b}L_{c} (II),
wherein:
M is a metal or an atom having a high EUV absorption cross-section;
each R is, independently, halo, optionally substituted alkyl, optionally substituted aryl, optionally substituted amino, optionally substituted alkoxy, or L;
each L is, independently, a ligand, an anionic ligand, a neutral ligand, a multidentate ligand, ion, or other moiety that is reactive with a counter-reactant, in which R and L with M, taken together, can optionally form a heterocyclyl group or in which R and L, taken together, can optionally form a heterocyclyl group;
a≥1; b≥1; and c≥1. s

6. The method of claim 1, wherein said conducting comprises:
heating the radiation-sensitive resist film in an absence of an oxygen-containing gas at a temperature from about 190° C. to about 350° C. for about 10 seconds to 5 minutes.

7. The method of claim 6, wherein said conducting further comprises, after said heating:
exposing the radiation-sensitive resist film to vacuum, an inert gas, or carbon dioxide (CO₂) at a temperature from about 0° C. to about 350° C. for a time period from about 10 seconds to 5 minutes.

8. The method of claim 1, wherein said conducting comprises:
exposing the radiation-sensitive resist film to vacuum, an inert gas, or CO₂ at a temperature between about 0° C. to about 350° C. for a time period between about 10 seconds to 5 minutes.

9. The method of claim 1, wherein said hardened resist film comprises a metal-oxygen-metal species, a metal carbonate species, or a metal oxycarbonate species.

10. The method of claim 1, further comprising, after said exposing:
treating the exposed resist film with an oxygen-containing agent.

11. The method of claim 10, wherein the oxygen-containing agent is oxygen (O₂), ozone (O₃), or hydrogen peroxide (H₂O₂).

12. The method of claim 1, further comprising, after said exposing:
storing the exposed resist film in an inert environment.

13. The method of claim 1, wherein said developing comprises use of a developer selected from the group consisting of an alkaline developer, an acidic developer, and a deprotecting solvent.

14. The method of claim 13, wherein the developer comprises a quaternary alkylammonium hydroxide, tetramethylammonium hydroxide (TMAH), choline, a halide, hydrogen chloride (HCl), hydrogen fluoride (HF), an organic acid, formic acid, acetic acid, oxalic acid, or citric acid.

15. The method of claim 14, wherein the developer is a 0.5 wt. % to 10 wt. % solution and optionally comprises an oxidizer, a non-ionic surfactant, a salt, and/or a chelating agent.

16. The method of claim 1, wherein said exposing comprises:
exposing the radiation-sensitive resist film to a patterned radiation exposure, thereby providing the exposed film resist having a radiation exposed area and a radiation unexposed area.

17. The method of claim 16, wherein said developing comprises:
removing the radiation exposed area to provide the pattern, wherein the radiation unexposed area comprises a carbonate species.

18. The method of claim 1, wherein the substrate comprises a hard mask and/or an underlayer.

19. The method of claim 1, wherein the radiation-sensitive resist film comprises an organometallic oxide film or an organometallic oxide hydroxide film.

20. The method of claim 1, wherein the radiation-sensitive resist film comprises tin (Sn), indium (In), bismuth (Bi), antimony (Sb), tellurium (Te), an oxide thereof, an alloy thereof, or a combination thereof.

21. An apparatus for processing a substrate, the apparatus comprising:
one or more process chambers, each process chamber comprising a chuck or a pedestal; and
one or more gas inlets into the one or more process chambers and associated flow-control hardware; and
a controller having at least one processor and a memory, wherein
the at least one processor and the memory are communicatively connected with one another,
the at least one processor is at least operatively connected with the flow-control hardware, and
the memory stores computer-executable instructions for controlling the at least one processor to at least control the flow-control hardware and for causing the method of claim 1.
